(19) United States
(12) Patent Application Publication
(10) Pub. No.: US 2024/0297145 A1
(43) Pub. Date: Sep. 5, 2024

(54) METHOD OF MANUFACTURING SEMICONDUCTOR DEVICE

(71) Applicant: Kioxia Corporation, Tokyo (JP)

(72) Inventors: Miki TOSHIMA, Nagoya (JP); Sadatoshi MURAKAMI, Yokkaichi (JP)

(73) Assignee: Kioxia Corporation, Tokyo (JP)

(21) Appl. No.: 18/592,124

(22) Filed: Feb. 29, 2024

(30) Foreign Application Priority Data
Mar. 1, 2023 (JP) 2023-031384

(51) Int. Cl. H01L 23/00; H01L 21/762

(52) U.S. Cl. CPC H01L 24/80; H01L 21/76254; H01L 2224/80895; H01L 2224/80896

(57) ABSTRACT

A method of manufacturing a semiconductor device according to one embodiment includes: forming, on a first substrate, a first layer having a refractive index lower than a refractive index of the first substrate; forming, on the first layer, a second layer having a refractive index lower than a refractive index of the first layer; forming a first circuit layer on the second layer; bonding the first and second substrate after forming the first circuit layer; irradiating a back surface of the first substrate with a laser beam after bonding the first substrate and the second substrate; and peeling the first substrate so that the first circuit layer remains on a side of the second substrate after irradiating the back surface of the first substrate with the laser beam.

### CROSS-REFERENCE TO RELATED APPLICATIONS

This application is based upon and claims the benefit of priority from Japanese Patent Application No. 2023-031384, filed Mar. 1, 2023, the entire contents of which are incorporated herein by reference.

### FIELD

Embodiments described herein relate generally

to a method of manufacturing a semiconductor device.

### BACKGROUND

A three-dimensional stacking technique for three-dimensionally stacking semiconductor circuit substrates is known.

### BRIEF DESCRIPTION OF DRAWINGS

FIG. 1 is a schematic view illustrating an outline of a process of reusing a semiconductor substrate.

FIG. 2 is a schematic view illustrating an

example of a configuration of a semiconductor device having a bonding structure.

FIG. 3 is a perspective view illustrating an example of an external appearance of a semiconductor device according to a first embodiment.

FIG. 4 is a cross-sectional view illustrating an example of a cross-sectional structure of the semiconductor device according to the first embodiment.

FIG. 5 is a flowchart illustrating an example of a method of manufacturing the semiconductor device according to the first embodiment.

FIG. 6 is a cross-sectional view illustrating

an example of a cross-sectional structure in a manufacturing process of the semiconductor device according to the first embodiment.

FIG. 7 is a schematic diagram illustrating an example of a structure of an object to be irradiated with a laser beam in the semiconductor device according to the first embodiment.

FIG. 8 is a graph illustrating an example of a relationship among a fluctuation range and an average value of a light absorption rate of a peeling layer with respect to a laser beam, the thickness of an oxide film, and the thickness of an antireflection film in the semiconductor device according to the first embodiment.

FIG. 9 is a schematic view illustrating an example of a structure of an object to be irradiated with a laser beam, an incident laser beam, and generated reflected light beams in a semiconductor device according to a comparative example.

FIG. 10 is a schematic diagram illustrating the example of the structure of the object to be irradiated with the laser beam, an incident laser beam, and generated reflected light beams in the semiconductor device according to the first embodiment.

FIG. 11 is a graph illustrating a result of an optical simulation regarding fluctuations in a light absorption rate of a peeling layer with respect to a laser beam wavelength in each of the first embodiment and the comparative example.

FIG. 12 is a plan view illustrating an example of a planar layout of a peeling layer formed on a first wafer used for manufacturing a semiconductor device according to a second embodiment.

FIG. 13 is a plan view illustrating an example of the planar layout of the peeling layer formed on the first wafer used for manufacturing the semiconductor device according to the second embodiment.

FIG. 14 is a cross-sectional view illustrating an example of a cross-sectional structure of the first wafer used for manufacturing the semiconductor device according to the second embodiment.

FIG. 15 is a table illustrating an example of properties of members used for manufacturing the semiconductor device according to the second embodiment.

FIG. 16 is a flowchart illustrating an example of a method of manufacturing the semiconductor device according to the second embodiment.

FIG. 17 is a schematic diagram illustrating an example of a structure of an object to be irradiated with a laser beam in the semiconductor device according to a second embodiment.

FIG. 18 is a graph illustrating a result of an optical simulation regarding fluctuations in a light absorption rate of a peeling layer with respect to a laser beam wavelength in each of the second embodiment and the comparative example.

FIG. 19 is a schematic view illustrating an example of a light absorption rate distribution of the peeling layer in a peeling process of the second embodiment.

FIG. 20 is a flowchart illustrating an example of a method of manufacturing a semiconductor device according to a third embodiment.

FIG. 21 is a schematic diagram illustrating an example of a structure of an object to be irradiated with a laser beam in a semiconductor device according to the third embodiment.

FIG. 22 is a graph illustrating a result of an optical simulation regarding fluctuations in a light absorption rate of a peeling layer with respect to a laser beam wavelength in each of the third embodiment and the comparative example.

FIG. 23 is a block diagram illustrating an example of an overall configuration of a semiconductor device according to a fourth embodiment.

FIG. 24 is a circuit diagram illustrating an example of a circuit configuration of a memory cell array included in the semiconductor device according to the fourth embodiment.

FIG. 25 is a plan view illustrating an example of a planar layout of the memory cell array included in the semiconductor device according to the fourth embodiment.

FIG. 26 is a plan view illustrating an example of a planar layout of a memory region of the semiconductor device according to the fourth embodiment.

FIG. 27 is a cross-sectional view taken along line XXVII-XXVII of FIG. 26 and illustrating an example of a cross-sectional structure of a first wafer used for manufacturing the semiconductor device according to the fourth embodiment.

FIG. 28 is a cross-sectional view taken along line XXVIII-XXVIII in FIG. 27 and illustrating an example of a cross-sectional structure of a memory pillar in the semiconductor device according to the fourth embodiment.

FIG. 29 is a cross-sectional view illustrating an example of a cross-sectional structure of the semiconductor device according to the fourth embodiment.

FIG. 30 is a graph illustrating a relationship between a refractive index and an extinction coefficient of SiO₂ with respect to a wavelength of a laser beam.

FIG. 31 is a table illustrating a relationship between a wavelength of a laser beam and reflectance with respect to Si in a method of manufacturing a semiconductor device according to a fifth embodiment.

FIG. 32 is a schematic diagram illustrating an example of a structure of an object to be irradiated with a laser beam in the semiconductor device according to the fifth embodiment and an example of a combination of laser beams used.

FIG. 33 is a graph illustrating a result of an optical simulation regarding fluctuations in a light absorption rate of a peeling layer with respect to a laser beam wavelength in each of the fifth embodiment and the comparative example.

FIG. 34 is a table illustrating a result of an optical simulation regarding a fluctuation range of a light absorption rate and an average light absorption rate for each combination of laser beams in the method of manufacturing the semiconductor device according to the fifth embodiment.

FIG. 35 is a schematic diagram illustrating a method for emitting a laser beam in a first modification of the fifth embodiment.

FIG. 36 is a schematic diagram illustrating a method for emitting a laser beam in a second modification of the fifth embodiment.

### DETAILED DESCRIPTION

In general, according to one embodiment, a method of manufacturing a semiconductor device in which a first substrate and a second substrate on which a first circuit layer and a second circuit layer different from each other are formed, respectively are bonded, the method includes: forming, on the first substrate, a first layer having a refractive index lower than a refractive index of the first substrate; forming, on the first layer, a second layer having a refractive index lower than a refractive index of the first layer; forming the first circuit layer on the second layer; bonding a front surface of the first substrate and a front surface of the second substrate after forming the first circuit layer;

irradiating a back surface of the first substrate with a laser beam after bonding the first substrate and the second substrate; and peeling the first substrate so that the first circuit layer remains on a side of the second substrate after irradiating the back surface of the first substrate with the laser beam.

Hereinafter, each embodiment will be described with reference to the drawings. Each embodiment exemplifies an apparatus and a method for embodying the technical idea of the invention. The drawings are schematic or conceptual. Dimensions, ratios, and the like in each drawing are not necessarily the same as actual ones. The illustration of configurations is omitted as appropriate. Hatching added to plan views is not necessarily related to the materials and properties of constituent elements. In the present specification, constituent elements having substantially the same function and configuration are denoted by the same reference signs. Numbers, characters, and the like added to reference signs are referred to by the same reference signs and are used to distinguish between similar elements.

### <0> Outline of Process of Reusing Semiconductor Substrate

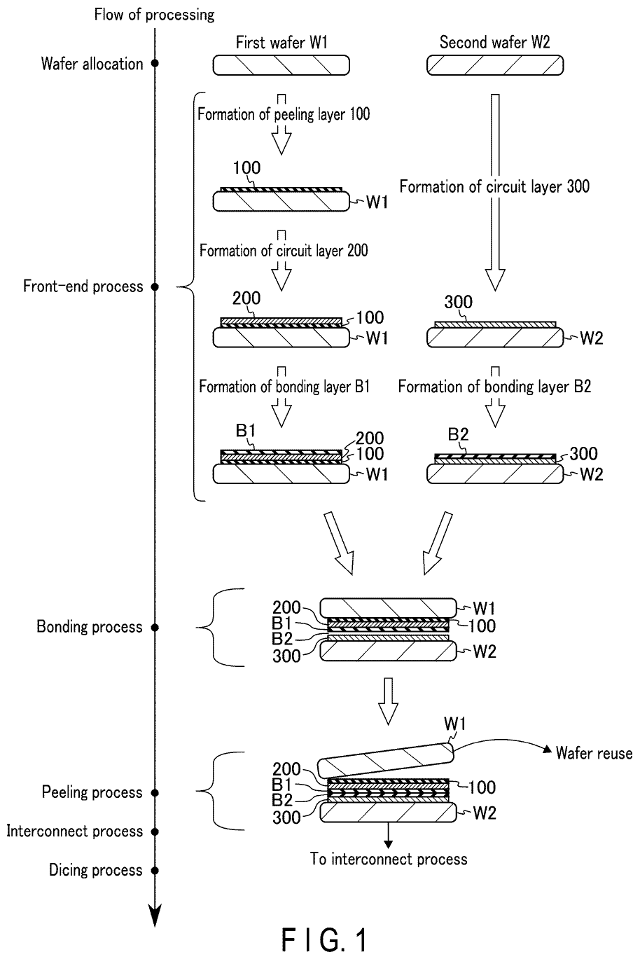

First, an outline of a process of reusing a wafer will be described. FIG. 1 is a schematic diagram illustrating the outline of the process of reusing a wafer. As illustrated in FIG. 1, a semiconductor device in the present specification is formed by bonding two semiconductor circuit substrates each having a semiconductor circuit formed thereon and by separating the bonded semiconductor circuit substrates for each chip. Hereinafter, the semiconductor circuit substrate is referred to as a “wafer”. The process of bonding two wafers is referred to as “bonding process”. A “front surface of the wafer” is a surface on a side where the semiconductor circuit is formed. A “back surface of the wafer” is a surface opposite to the front surface of the wafer. A wafer disposed on an upper side during the bonding process is referred to as a “first wafer W1”. A wafer disposed on a lower side during the bonding process is referred to as a “second wafer W2”.

In a manufacturing process of the semiconductor device, first, a combination of the first wafer W1 and the second wafer W2 is prepared (“wafer allocation”). In the present example, each of the first wafer W1 and the second wafer W2 is a silicon substrate. The first wafer W1 is used for forming a first semiconductor circuit. The second wafer W2 is used for forming a second semiconductor circuit different from the first semiconductor circuit. The semiconductor device is configured to function using a combination of the first semiconductor circuit and the second semiconductor circuit. The design of each of the first semiconductor circuit and the second semiconductor circuit can be appropriately changed according to the function of the semiconductor device.

Next, the first semiconductor circuit is formed on the first wafer W1 by a front-end process of each of the first wafer W1, and the second semiconductor circuit is formed on the second wafer W2 by a front-end process of the second wafer W2. In addition, a layer for achieving the process of reusing a wafer is formed before the formation of the first semiconductor circuit. Specifically, a peeling layer 100, a circuit layer 200, and a bonding layer B1 are sequentially formed on the first wafer W1. The peeling layer 100 is a layer used as a starting point for separating the first semiconductor circuit formed on the first wafer W1 from the first wafer W1. The peeling layer 100 includes a material (for example, a silicon oxide film) having a property of absorbing a laser beam used in peeling process to be described later. The circuit layer 200 is a layer including the first semiconductor circuit. The bonding layer B1 is a layer including a bonding pad used for connection with the first semiconductor circuit formed on the first wafer W1. A circuit layer 300 and a bonding layer B2 are sequentially formed on the second wafer W2. The circuit layer 300 is a layer including the second semiconductor circuit. The bonding layer B2 is a layer including a bonding pad used for connection with the bonding pad formed on the bonding layer B1.

Next, the bonding process of the first wafer W1 and the second wafer W2 is executed. Specifically, a bonding device disposes a front surface of the first wafer W1 and a front surface of the second wafer W2 to face each other. Then, the bonding device adjusts an overlapping position of a pattern formed on the front surface of the first wafer W1 and a pattern formed on the front surface of the second wafer W2 and bonds the front surface of the first wafer W1 and the front surface of the second wafer W2 to each other. As a result, the bonding layer B1 of the first wafer W1 and the bonding layer B2 of the second wafer W2 are bonded, and the first semiconductor circuit provided on the first wafer W1 and the second semiconductor circuit provided on the second wafer W2 are electrically connected.

Next, the peeling process of the first wafer W1 is executed. In the peeling process in the present specification, a peeling method using the laser beam is used. Specifically, first, a back surface of the first wafer W1 is irradiated with the laser beam. Then, a crack is generated from a peripheral edge portion between the first wafer W1 and the second wafer W2 that are bonded. Then, the first wafer W1 is peeled with the peeling layer 100 as a starting point. As a result, a structure in which the circuit layer 300, the bonding layer B2, the bonding layer B1, and the circuit layer 200 are sequentially stacked on the second wafer W2 remains. The peeled first wafer W1 is reused (“wafer reuse”) after surface processing such as removal of a residual film is executed.

Thereafter, an interconnect process is executed with respect to the second wafer W2. The interconnect process includes, for example, a process of forming a pad used for connection between the first semiconductor circuit and/or the second semiconductor circuit and an external device, a process of forming a pad for supplying power to the semiconductor device, and the like. After the interconnect process is completed, the second wafer W2 is separated into chip units by dicing process. As a result, the semiconductor device having a bonding structure is formed. Note that in the present specification, a case where the semiconductor device is formed using two wafers is exemplified, but the present invention is not limited to this. The number of wafers used for forming the semiconductor device may be three or more. In other words, the semiconductor device may have a bonding structure using a total of three or more wafers.

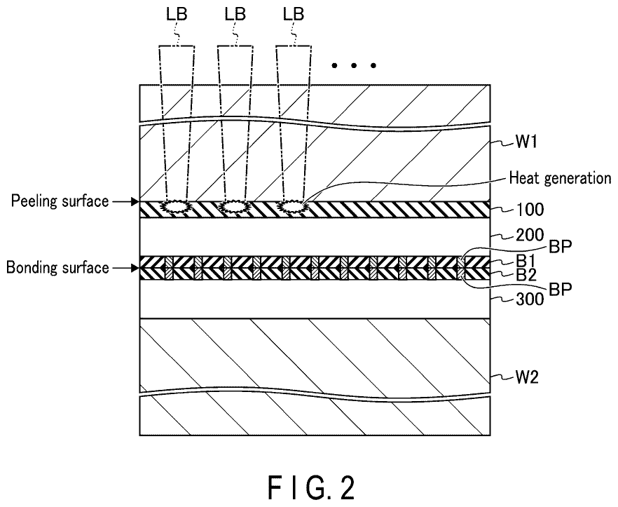

FIG. 2 is a schematic diagram illustrating an example of a configuration of the semiconductor device having the bonding structure. FIG. 2 also illustrates how the back surface of the first wafer W1 is irradiated with a laser beam LB in the peeling process of the first wafer W1. As illustrated in FIG. 2, each of the bonding layers B1 and B2 includes a plurality of bonding pads BP. Each bonding pad BP of the bonding layer B1 is connected to the first semiconductor circuit (not illustrated). Each bonding pad BP of the bonding layer B2 is connected to the second semiconductor circuit (not illustrated). In addition, each of the plurality of bonding pads BP of the bonding layer B1 is disposed so as to face each of the plurality of bonding pads BP of the bonding layer B2. A set of the bonding pads BP disposed to face each other is bonded by the bonding process and is electrically connected.

In the peeling process of the first wafer W1, the back surface of the first wafer W1 is irradiated with the laser beam LB at a predetermined interval. As the laser beam LB, for example, a CO₂ laser having a wavelength of 9.3 micrometers (μm) is used. The CO₂ laser has a property of passing through the silicon substrate and being absorbed by the silicon oxide film. In other words, the transmittance of the first wafer W1 with respect to the laser beam LB is higher than the transmittance of the silicon oxide film with respect to the laser beam LB. Note that the laser beam LB incident on the peeling layer 100 is influenced by interference of a reflected light beam at an interface between the first wafer W1 and the peeling layer 100. Therefore, a light absorption rate of the peeling layer 100 with respect to the laser beam LB changes according to the thickness of the first wafer W1.

In a case where the laser beam LB emitted to the back surface of the first wafer W1 passes through the first wafer W1 and is emitted to the silicon oxide film included in the peeling layer 100, the silicon oxide film absorbs the laser beam LB to generate heat. Then, the heat generated in the peeling layer 100 propagates to a vicinity of the interface between the first wafer W1 and the peeling layer 100. As a result, a portion of the first wafer W1 in the vicinity of the interface with the peeling layer 100 is plastically deformed according to the propagated heat. The interface between the plastically deformed first wafer W1 and the peeling layer 100 is more easily peeled than before the irradiation of the laser beam LB. As a result, in the peeling process, the first wafer W1 and the peeling layer 100 can be peeled with a space between the first wafer W1 and the peeling layer 100 as a peeling surface.

### <1>First Embodiment

A method of manufacturing a semiconductor device 1 according to a first embodiment suppresses fluctuations in a light absorption rate of a peeling layer 100 with respect to a laser beam LB emitted to a back surface of a first wafer W1 by inserting an antireflection layer 110 into the peeling layer 100. Hereinafter, details of the first embodiment will be described.

### <1-1> Configuration

First, a configuration of the semiconductor device 1 according to the first embodiment will be described. In the drawings referred to below, a three-dimensional Cartesian coordinate system is used. An X direction and a Y direction are directions intersecting each other and parallel to a front surface of a wafer. A Z direction is a direction intersecting with each of the X direction and the Y direction and corresponds to a vertical direction with respect to the front surface of the wafer (substrate). In the present specification, “up and down” is defined based on a direction along the Z direction. In addition, in the present specification, a direction away from a front surface side of the substrate as a reference is defined as a positive direction (upward).

### (External Appearance of Semiconductor Device 1)

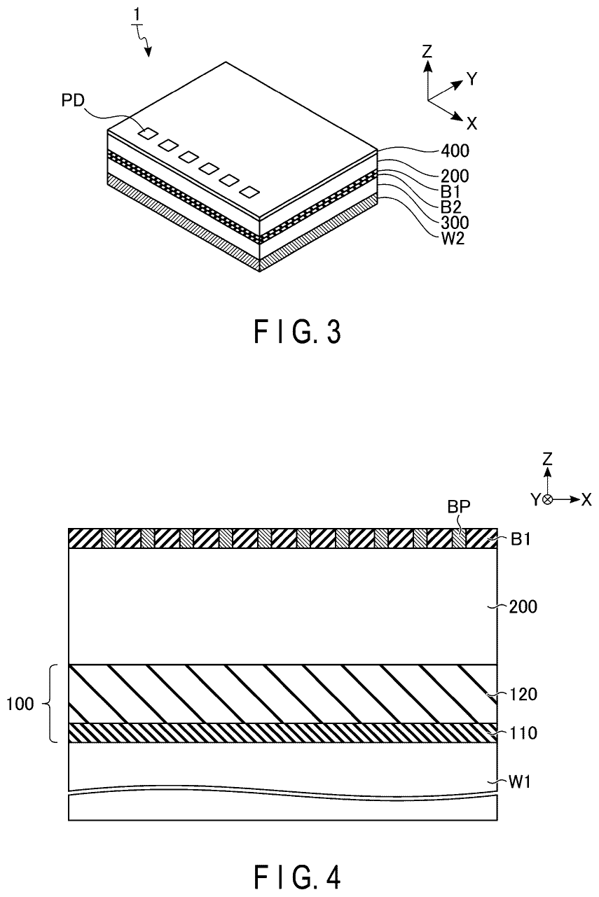

FIG. 3 is a perspective view illustrating an example of an external appearance of the semiconductor device 1 according to the first embodiment. As illustrated in FIG. 3, the semiconductor device 1 has, for example, a structure in which a second wafer W2, a circuit layer 300, a bonding layer B2, a bonding layer B1, a circuit layer 200, a peeling layer 100, and an interconnect layer 400 are stacked in order from the bottom. A boundary portion between the bonding layers B1 and B2 corresponds to a bonding surface between the first wafer W1 and the second wafer W2. The interconnect layer 400 includes, for example, a plurality of pads PD exposed on a surface of the semiconductor device 1. The plurality of pads PD is used for connection between the semiconductor device 1 and an external device. As described above, the semiconductor device 1 according to the first embodiment does not have the peeling layer 100 and the first wafer W1 as a final configuration.

### (Structure of First Wafer W1)

FIG. 4 is a cross-sectional view illustrating an example of a cross-sectional structure of the first wafer W1 before bonding of the semiconductor device 1 according to the first embodiment. FIG. 4 illustrates an example of a structure of the peeling layer 100, the circuit layer 200, and the bonding layer B1 formed on the first wafer W1 before the first wafer W1 is bonded to the second wafer W2, and FIG. 4 displays coordinate axes based on the first wafer W1. As illustrated in FIG. 4, the peeling layer 100 includes the antireflection layer 110 and a light absorption layer 120.

In the peeling layer 100, the antireflection layer 110 is provided on the first wafer W1. The light absorption layer 120 is provided on the antireflection layer 110. The circuit layer 200 is provided on the light absorption layer 120. A refractive index of the antireflection layer 110 is a value between a refractive index of the first wafer W1 and a refractive index of the light absorption layer 120. In other words, in the first embodiment, the antireflection layer 110 having a refractive index between the refractive index of the first wafer W1 and the refractive index of the light absorption layer 120 is inserted into an interface between the first wafer W1 and the light absorption layer 120 (peeling layer 100). The antireflection layer 110 is configured to reduce the intensity of a reflected light beam from the interface between the first wafer W1 and the light absorption layer 120.

As the light absorption layer 120, for example, a silicon oxide film is used. Note that it suffices that the light absorption layer 120 is configured so that the transmittance of the first wafer W1 with respect to the laser beam LB is higher than the transmittance of the light absorption layer 120 with respect to the laser beam LB. The antireflection layer 110 may be a layer in which the same member (medium) as the light absorption layer 120 and another member (medium) are patterned and mixed. In other words, the antireflection layer 110 may include a homogeneous medium having a refractive index between the refractive index of the first wafer W1 and the refractive index of the light absorption layer 120. Each of the antireflection layer 110 and the light absorption layer 120 may be referred to as an “interlayer film”.

### <1-2> Method of Manufacturing

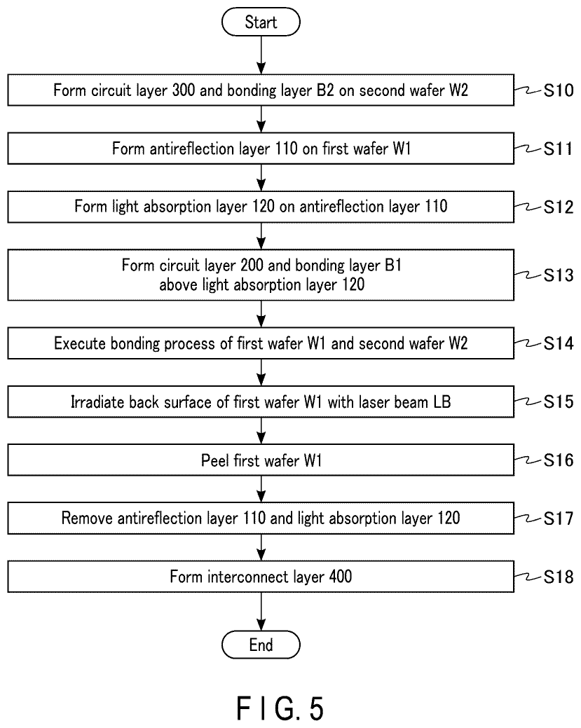

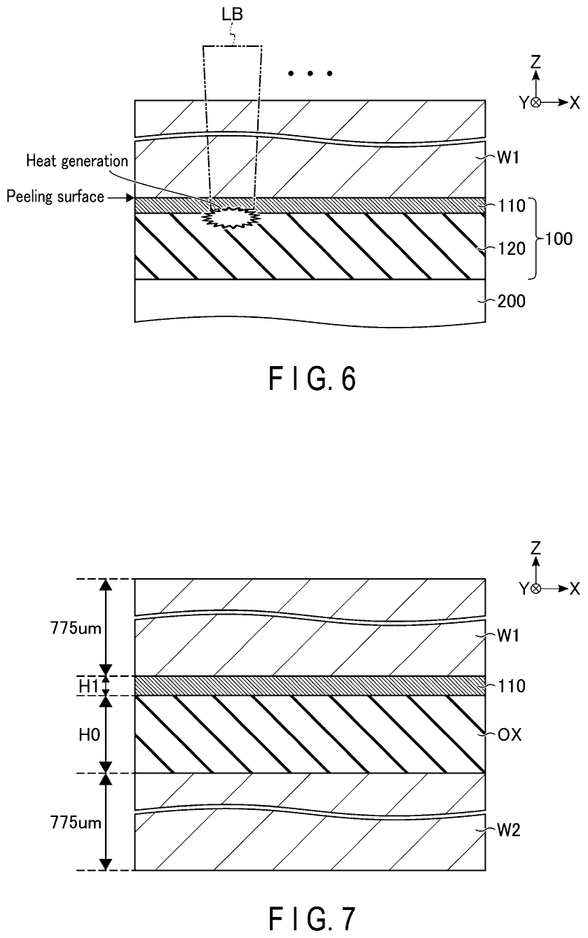

FIG. 5 is a flowchart illustrating an example of the method of manufacturing the semiconductor device 1 according to the first embodiment. FIG. 6 is a cross-sectional view illustrating an example of a cross-sectional structure in a manufacturing process of the semiconductor device 1 according to the first embodiment, the cross-sectional view extracting and illustrating a region in a vicinity of the peeling layer 100 and displaying coordinate axes based on the second wafer W2 (not illustrated). Hereinafter, the method of manufacturing the semiconductor device 1 according to the first embodiment will be described with reference to FIG. 5 as appropriate.

The circuit layer 300 and the bonding layer B2 are formed on the second wafer W2 (S10). The processing of S10 corresponds to a front-end process of the second wafer W2. In addition, the antireflection layer 110 is formed on the first wafer W1 (S11). Next, the light absorption layer 120 is formed on the antireflection layer 110 (S12). Next, the circuit layer 200 and the bonding layer B1 are formed above the light absorption layer 120 (S13). The processing of S11 to S13 corresponds to a front-end process of the first wafer W1. The processing of S10 and the processing of S11 to S13 may be executed in parallel, or the order of these processing processes may be switched.

Next, the bonding process of the first wafer W1 and the second wafer W2 is executed (S14) . Through the processing of S14, the bonding layer B1 formed on the first wafer W1 and the bonding layer B2 formed on the second wafer W2 are bonded, and a first semiconductor circuit included in the circuit layer 200 and a second semiconductor circuit included in the circuit layer 300 are electrically connected.

Next, as illustrated in FIG. 6, the back surface of the first wafer W1 is irradiated with the laser beam LB (S15). The laser beam LB used in the processing of S15 is, for example, a CO₂ laser of non-polarization having a wavelength of 9.2 to 10.8 μm. In the processing of S15, the laser beam LB passes through the first wafer W1 and reaches the peeling layer 100. At this time, the light absorption layer 120 absorbs the laser beam LB at a light absorption rate corresponding to an interference effect by a reflected light beam at the back surface of the first wafer W1 (interface with air) and a reflected light beam at an interface between the first wafer W1 and the antireflection layer 110, and a reflected light beam at an interface between the antireflection layer 110 and the light absorption layer 120. Then, the light absorption layer 120 generates heat by absorbing the laser beam LB, and a vicinity of a portion in contact with a peeling surface of the first wafer W1 is plastically deformed based on the heat generated in the light absorption layer 120. Then, an irradiation position of the laser beam LB is changed, and the back surface of the first wafer W1 is irradiated with the laser beam LB at a predetermined interval.

Next, the first wafer W1 is peeled (S16). Through the processing of S16, the first wafer W1 is peeled with a space between the antireflection layer 110 and the first wafer W1 as a peeling surface, and a structure in which the circuit layer 300 and the circuit layer 200 remain is formed on the second wafer W2. Next, the antireflection layer 110 and the light absorption layer 120 are removed (S17). In the processing of S17, part of the circuit layer 200 may be removed. Next, the interconnect layer 400 is formed (S18). In the processing of S18, the plurality of pads PD connected to either of the first semiconductor circuit included in the circuit layer 200 and the second semiconductor circuit included in the circuit layer 300 is formed on the surface of the semiconductor device 1. As a result, a structure of the semiconductor device 1 illustrated in FIG. 3 is formed.

### (Method for Optimizing Design Parameters of Peeling Layer 100)

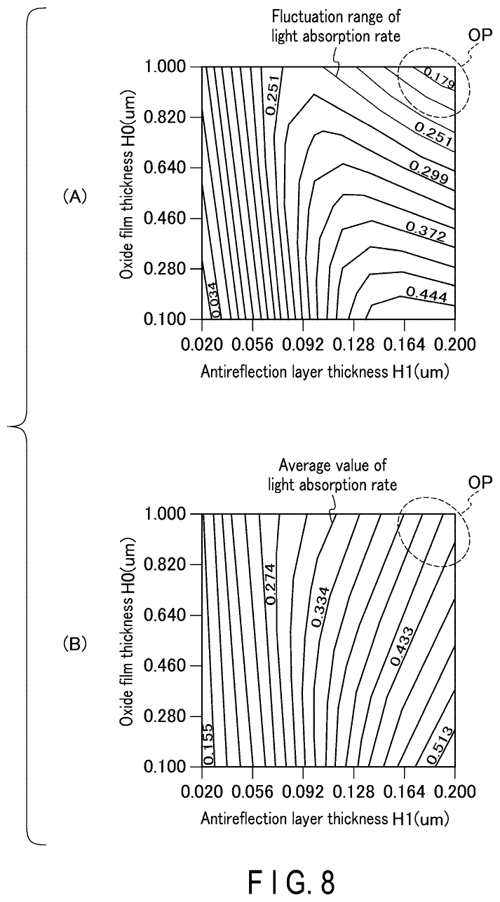

Hereinafter, a method for optimizing design parameters of the peeling layer 100 in the semiconductor device 1 according to the first embodiment will be described with reference to FIGS. 7 and 8.

FIG. 7 is a schematic diagram illustrating an example of a structure of an object to be irradiated with a laser beam in the semiconductor device 1 according to the first embodiment and schematically illustrates a structure of the semiconductor device 1 after the first wafer W1 and the second wafer W2 are bonded together. In addition, FIG. 7 illustrates coordinate axes based on the second wafer W2. As illustrated in FIG. 7, in the present example, the semiconductor device 1 has a configuration in which portions corresponding to the circuit layers 200 and 300, the bonding layers B1 and B2, and the light absorption layer 120 are replaced with a silicon oxide film OX. In the present example, the silicon oxide film OX functions as one light absorption layer 120. In the present example, each of the first wafer W1 and the second wafer W2 is a silicon substrate. In addition, the thickness of each of the first wafer W1 and the second wafer W2 is set to 775 μm. In the present example, the thickness of the silicon oxide film OX is set to 0.4 μm.

In the present example, the antireflection layer 110 is a film having a refractive index of 2.5. In addition, the thickness of the antireflection layer 110 is set to 0.1 μm. Hereinafter, the thickness of the first wafer W1 is referred to as “wafer thickness”, the thickness of the silicon oxide film OX is referred to as “oxide film thickness H0”, and the thickness of the antireflection layer 110 is referred to as “antireflection layer thickness H1”.

FIG. 8 is a graph illustrating a simulation result illustrating a relationship among a fluctuation range and an average value of a light absorption rate of the peeling layer 100 with respect to the laser beam LB, the oxide film thickness H0, and the antireflection layer thickness H1 in the semiconductor device 1 according to the first embodiment. FIG. 8 illustrates a simulation result related to a light absorption rate of the light absorption layer 120 in a case where the back surface of the first wafer W1 of the semiconductor device 1 illustrated in FIG. 7 is irradiated with the laser beam LB. A contour line in (A) of FIG. 8 illustrates a fluctuation range of the light absorption rate caused by a change in the wafer thickness. A contour line in (B) of FIG. 8 illustrates an average value of the light absorption rate caused by a change in the wafer thickness. A vertical axis in each of (A) and (B) of FIG. 8 is associated with the oxide film thickness H0. A horizontal axis of each of (A) and (B) of FIG. 8 is associated with the antireflection layer thickness H1.

In the case of optimizing the design parameters of the peeling layer 100, first, the fluctuation range and the average value of the light absorption rate in a case where respective conditions of the oxide film thickness H0 and the antireflection layer thickness H1 are changed are evaluated. As an evaluation result of the fluctuation range of the light absorption rate in the present example, the simulation result as illustrated in FIG. 8A is obtained. As an evaluation result of the average value of the light absorption rates in the present example, the simulation result as illustrated in FIG. 8B is obtained. As a property of the peeling layer 100, the fluctuation range of the light absorption rate is preferably small, and the average value of the light absorption rate is preferably large. Therefore, as the design parameters of the peeling layer 100, a region in which the fluctuation range of the light absorption rate is small and the average value of the light absorption rate is large is preferably selected. For example, as the design parameters of the peeling layer 100 in the present example, a set of the oxide film thickness H0 and the antireflection layer thickness H1 corresponding to a region OP illustrated in each of (A) and (B) of FIG. 8 is selected.

In the case of optimizing the design parameters, a threshold value or a range may be set in advance for each of the oxide film thickness H0 and the antireflection layer thickness H1. In addition, a value such that the fluctuation range of the light absorption rate becomes small and the average value of the light absorption rate becomes large may be calculated based on a formula illustrating the fluctuation range of the light absorption rate and a formula illustrating the average value of the light absorption rate. In the processing of each of S11 and S12 illustrated in FIG. 5, processing parameters may be adjusted so that the processing parameters approach the oxide film thickness H0 and the antireflection layer thickness H1 based on the value of the wafer thickness measured in advance.

### <1-3> Effects of First Embodiment

The method of manufacturing the semiconductor device 1 according to the first embodiment described above can suppress a manufacturing cost of a semiconductor device 1. Hereinafter, details of effects of the first embodiment will be described.

As a method of manufacturing a semiconductor device having a bonding structure, there is known a method in which a first wafer W1 is bonded to a second wafer W2, and then the first wafer W1 is removed by a back grinding (back surface cutting) processing or the like. Meanwhile, if the first wafer W1 after the bonding can be reused for manufacturing another semiconductor device, it is possible to suppress wastewater treatment and a wafer cost associated with back grinding processing and the like. Therefore, there is studied “laser peeling” in which the peeling layer 100 is formed before the first semiconductor circuit is formed on the first wafer W1, and the peeling process with the peeling layer 100 as a starting point is executed by laser irradiation.

In the laser peeling, for example, the silicon oxide film included in the peeling layer 100 is heated by the laser beam LB, whereby the vicinity of the interface between the first wafer W1 and the peeling layer 100 is plastically deformed. Then, a crack is caused to occur on the bonding surface of the first wafer W1 and the second wafer W2, whereby the first wafer W1 can be peeled with the peeling layer 100 as a starting point. However, in the laser peeling, the light absorption rate in the peeling layer 100 changes due to an interference effect of the reflected light beam at the back surface of the first wafer W1 (interface with air) and a reflected light beam at an interface between the first wafer W1 and the peeling layer 100. In other words, the light absorption rate of the peeling layer 100 fluctuates according to a magnitude of the interference effect of these light beams. For example, the magnitude of the interference effect of the light beams changes according to the wafer thickness. In the laser peeling, a stable peeling process becomes possible by causing the peeling layer 100 to absorb specified power. In other words, fluctuations in the light absorption rate can be a factor for the peeling process of the first wafer W1 by the laser peeling to be unstable.

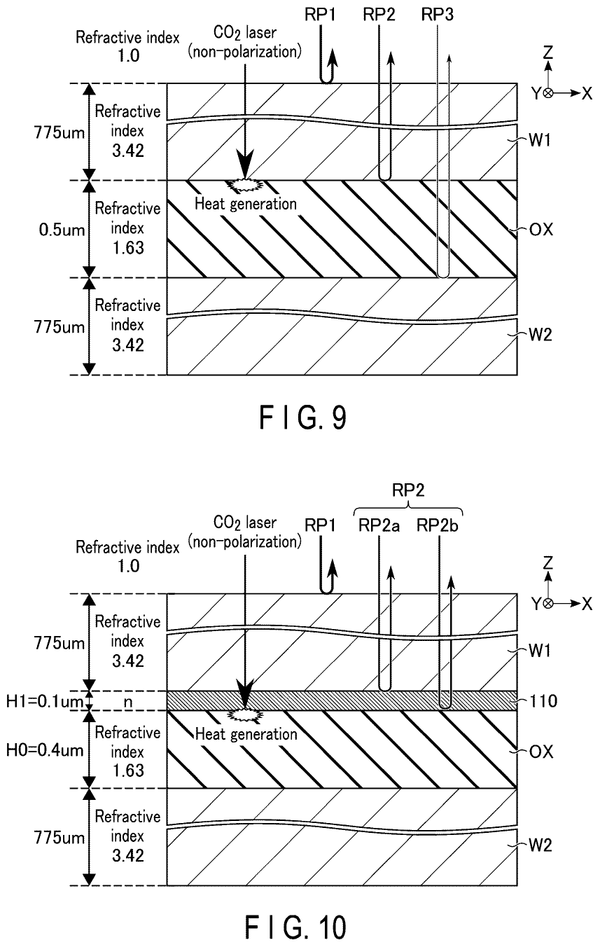

Here, a factor of the change in the light absorption rate according to the wafer thickness will be described. FIG. 9 is a schematic diagram illustrating an example of a structure of an object to be irradiated with a laser beam, an incident laser beam LB, and generated reflected light beams in a semiconductor device according to a comparative example. In addition, FIG. 9 illustrates coordinate axes based on a second wafer W2. As illustrated in FIG. 9, the semiconductor device according to the comparative example has a configuration in which the antireflection layer 110 is replaced with a silicon oxide film OX with respect to the structure illustrated in FIG. 7. Note that a refractive index of air is 1.0, a refractive index of each of a first wafer W1 and the second wafer W2 is 3.42, and a refractive index of a silicon oxide film OX is 1.63. The thickness of the silicon oxide film OX (oxide film thickness H0) in the comparative example is 0.5 μm.

In the comparative example, if the back surface of the first wafer W1 is irradiated with a CO₂ laser of non-polarization (wavelength: 9.2 to 10.8 μm), for example, three types of reflected light beams RP1 to RP3 are generated. The reflected light beam RP1 corresponds to a light beam that is the CO₂ laser is reflected at an interface between air and the first wafer W1. The intensity of the reflected light beam RP1 is large because a refractive index difference between air and silicon is large. The reflected light beam RP2 corresponds to a light beam reflected at an interface between the first wafer W1 and the silicon oxide film OX. The intensity of the reflected light beam RP2 is large because a refractive index difference between silicon and the silicon oxide film OX is large. The reflected light beam RP3 corresponds to a light beam reflected at an interface between the silicon oxide film OX and the second wafer W2. The intensity of the reflected light beam RP3 is small because the intensity of the reflected light beam RP3 is influenced by absorption by the silicon oxide film OX. Therefore, in the comparative example, an interference effect of the reflected light beams RP1 and RP2 becomes relatively large.

In contrast to this, the semiconductor device 1 according to the first embodiment has a configuration in which the antireflection layer 110 is inserted into the interface between the first wafer W1 and the silicon oxide film OX. FIG. 10 is a schematic diagram illustrating the example of the structure of the object to be irradiated with the laser beam in the semiconductor device 1 according to the first embodiment, an incident laser beam, and generated reflected light beams. In addition, FIG. 10 illustrates coordinate axes based on the second wafer W2. FIG. 10 schematically illustrates the laser beam LB and the reflected light beams RP1 and

RP2 with respect to the structure used in the first embodiment illustrated in FIG. 7. Note that a refractive index n of the antireflection layer 110 satisfies 1.63<n<3.42.

In the first embodiment, if the back surface of the first wafer W1 is irradiated with a CO₂ laser of non-polarization (wavelength: 9.2 to 10.8 μm), the reflected light beam RP1 similar to that in the comparative example is generated. In the first embodiment, the reflected light beam RP2 described in the comparative example is divided into two reflected light beams RP2a and RP2b. Specifically, the reflected light beam RP2a corresponds to a light beam reflected at an interface between the first wafer W1 and the antireflection layer 110. The reflected light beam RP2b corresponds to a light beam reflected at an interface between the antireflection layer 110 and the silicon oxide film OX. The sum of the intensities of the reflected light beams RP2a and RP2b is reduced as compared with that of the reflected light beam RP2 in the comparative example because each of a refractive index difference at the interface between the first wafer W1 and the antireflection layer 110 and a refractive index difference at the interface between the antireflection layer 110 and the silicon oxide film OX are smaller than a refractive index difference in the case of the reflected light beam RP2 in the comparative example. In addition, in the first embodiment, the phases of the reflected light beams RP2a and RP2b are shifted according to the thickness of the antireflection layer 110. As a result, in the first embodiment, the fluctuation range due to interference by the reflected light beams RP1 and RP2 can be reduced as compared with the comparative example.

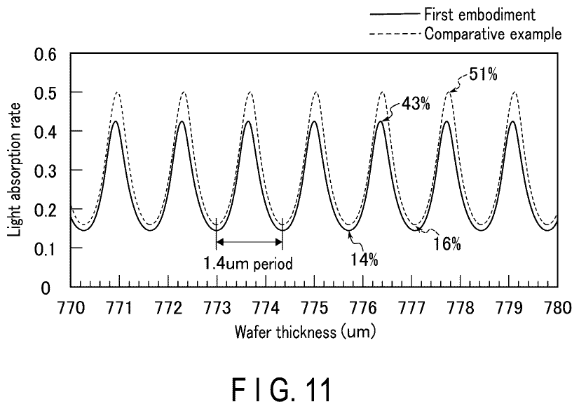

FIG. 11 is a graph illustrating a result of an optical simulation regarding fluctuations in a light absorption rate of the peeling layer 100 in each of the first embodiment and the comparative example. A horizontal axis illustrates the wafer thickness (μm). A vertical axis illustrates the light absorption rate. A broken line corresponds to the light absorption rate in a configuration of the comparative example illustrated in FIG. 9. A solid line illustrates the light absorption rate in a configuration of the first embodiment illustrated in FIG. 10. As illustrated in FIG. 11, the light absorption rate periodically changes according to the wafer thickness. In the present example, the light absorption rate of each of the first embodiment and the comparative example fluctuates at a period of 1.4 μm. Then, the light absorption rate in the comparative example fluctuates in a range of 16% to 51%. In other words, the fluctuation range of the light absorption rate in the comparative example is about 35%. Meanwhile, the light absorption rate in the first embodiment fluctuates in a range of 14% to 43%. In other words, the fluctuation range of the light absorption rate in the first embodiment is about 29%.

As described above, the method of manufacturing the semiconductor device 1 according to the first embodiment can suppress fluctuations in the light absorption rate based on fluctuations in the wafer thickness in a peeling process of the first wafer W1 using the laser peeling. In other words, the method of manufacturing the semiconductor device 1 according to the first embodiment can suppress fluctuations in energy absorbed by the peeling layer 100 in the laser peeling and can achieve a stable peeling process. As a result, the method of manufacturing the semiconductor device 1 according to the first embodiment can improve a yield of a manufacturing process of a semiconductor device that reuses the first wafer W1, and the method can suppress a manufacturing cost of the semiconductor device.

### <2> Second Embodiment

A method of manufacturing a semiconductor

device 1 according to a second embodiment uses an antireflection layer 110a including a homogeneous medium to suppress fluctuations in a light absorption rate of a peeling layer 100 with respect to a laser beam LB emitted to a back surface of a first wafer W1. Hereinafter, details of the second embodiment will be described mainly on differences from the first embodiment.

### <2-1> Configuration

First, a configuration of the semiconductor device 1 according to the second embodiment will be described. The semiconductor device 1 according to the second embodiment has a configuration similar to the configuration of the first embodiment except that a structure of the peeling layer 100 formed in a manufacturing process is different. Hereinafter, the peeling layer 100 formed in the manufacturing process of the semiconductor device 1 according to the second embodiment is referred to as a “peeling layer 100a”.

### (1: Planar Layout of Peeling Layer 100a)

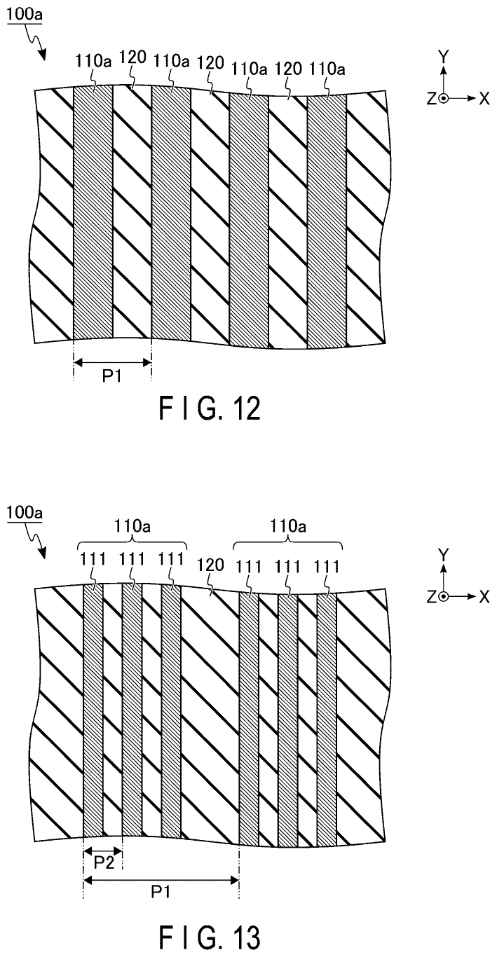

Each of FIGS. 12 and 13 is a plan view illustrating an example of a planar layout of the peeling layer 100a formed on the first wafer W1 used for manufacturing the semiconductor device 1 according to the second embodiment. FIGS. 12 and 13 correspond to first and second configuration examples of the peeling layer 100a, respectively.

As illustrated in FIG. 12, the peeling layer

100a has a plurality of antireflection layers 110a in a plan view. Each of the plurality of antireflection layers 110a has, for example, a portion provided while extending along a Y direction. The portion of each antireflection layer 110a provided while extending along the Y direction is disposed in a line-and-space pattern shape in a plan view, that is, at a substantially equal interval. In the present example, a light absorption layer 120 is provided in a portion corresponding to a space between the plurality of the antireflection layers 110a disposed in the line-and-space pattern.

As illustrated in FIG. 13, each antireflection layer 110a may be divided into a plurality of sub-patterns 111. Each of the plurality of sub-patterns 111 includes a material similar to a material of the above-described antireflection layer 110a. While corresponding to each antireflection layer 110a, each of the plurality of sub-patterns 111 has, for example, a portion provided while extending along the Y direction. The portion of each sub-pattern 111 provided while extending along the Y direction is disposed in a line-and-space pattern shape in a plan view, that is, at a substantially equal interval. In the present example, the light absorption layer 120 is provided in a portion corresponding to a space between the plurality of sub-patterns 111 disposed in a line-and-space pattern shape.

Hereinafter, a width of a line portion in a pattern formed in a line-and-space pattern shape is referred to as a “line width”, and a width of a space portion is referred to as a “space width”. A pitch at which the line portions of the plurality of antireflection layers 110a disposed in the line-and-space pattern are disposed is referred to as a “main pitch P1”. The main pitch P1 is designed to have dimensions based on a wavelength of the laser beam LB. Specifically, the main pitch P1 is designed to be one fifth or less of the wavelength of the laser beam LB. In addition, a pitch at which the line portions of the plurality of sub-patterns 111 disposed in a line-and-space pattern shape are disposed is referred to as a “sub-pitch P2”. The sub-pitch P2 is designed to be narrower than the main pitch P1. Furthermore, the sub-pitch P2 is designed to have dimensions such that each antireflection layer 110a does not overlap an adjacent antireflection layer 110a according to the number of sub-patterns 111 included in each antireflection layer 110a.

As described above, in the peeling layer 100a, the antireflection layer 110a is provided with a structure having a period (main pitch P1) sufficiently shorter than the wavelength of the laser beam LB. Therefore, a set of the antireflection layer 110a and the light absorption layer 120 at a height at which the antireflection layer 110a is provided can be regarded as a homogeneous medium (that is, a uniform film) for the laser beam LB based on an effective medium approximation (EMA) theory. The EMA theory is an analytical theory for regarding a structure having a period sufficiently shorter than a wavelength as a homogeneous medium. As one of the simplest models of EMA, there is known a linear EMA model that calculates an equivalent refractive index n and an extinction coefficient k from a volume ratio of a medium. In the second embodiment, the above-described homogeneous medium is designed to have a refractive index between a refractive index of the first wafer W1 and a refractive index of the light absorption layer 120.

Note that the peeling layer 100a may have a configuration such that the disposition of the plurality of antireflection layers 110a illustrated in FIGS. 12 and 13 is rotated by 90 degrees. In other words, it suffices that the peeling layer 100a has at least one of the plurality of antireflection layers 110a in which a portion extending along an X direction is disposed in a line-and-space pattern shape and the plurality of antireflection layers 110a in which a portion extending along the Y direction is disposed in a line-and-space pattern shape. A volume mixing ratio of the antireflection layer 110a and the light absorption layer 120 at the height at which the antireflection layer 110a is provided may be adjusted by the sub-pitch P2. A refractive index of the homogeneous medium may be referred to as an equivalent refractive index. The antireflection layer thickness H1 described in the first embodiment corresponds to a pattern height of the antireflection layer 110a in the second embodiment, that is, a film thickness of the homogeneous medium.

### (2: Structure of First Wafer W1)

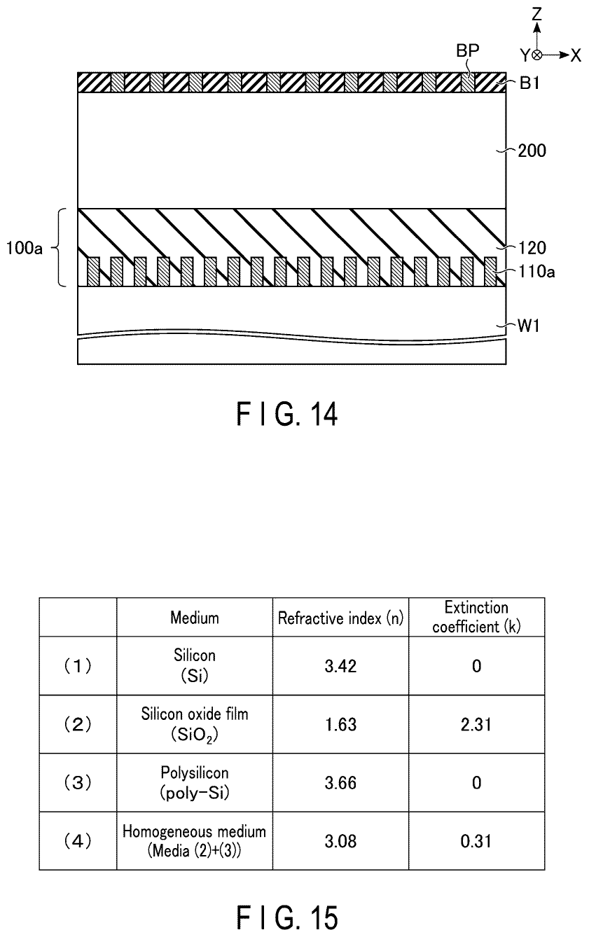

FIG. 14 is a cross-sectional view illustrating an example of a cross-sectional structure of the first wafer W1 used for manufacturing the semiconductor device 1 according to the second embodiment. FIG. 14 illustrates an example of a structure of the peeling layer 100a, a circuit layer 200, and a bonding layer B1 formed on the first wafer W1 before the first wafer W1 is bonded to a second wafer W2, and FIG. 14 displays coordinate axes based on the first wafer W1. As illustrated in FIG. 14, the peeling layer 100a includes the plurality of antireflection layers 110a and the light absorption layer 120.

In the peeling layer 100a, the plurality of antireflection layers 110a is provided on the first wafer W1. The light absorption layer 120 has a portion provided on the first wafer W1 and portions provided on an upper surface and a side surface of the antireflection layer 110a. In other words, the light absorption layer 120 is provided so as to cover a side surface and an upper surface of each of the plurality of antireflection layers 110a. In the second embodiment, the homogeneous medium including the plurality of antireflection layers 110a and a part of the light absorption layer 120 is inserted into an interface between the first wafer W1 and the light absorption layer 120. In other words, in a layer at a height at which the antireflection layer 110a is provided, the plurality of antireflection layers 110a and the light absorption layer 120 are configured to reduce the intensity of a reflected light beam from the interface between the first wafer W1 and the light absorption layer 120. As the antireflection layer 110a, for example, polysilicon is used. The antireflection layer 110a may be referred to as a “member”. In the peeling layer 100a, each of oxide film thickness H0 and antireflection layer thickness H1 is designed to suppress fluctuations in a light absorption rate.

### (3: Properties of Members Used for Manufacturing Semiconductor Device 1)

FIG. 15 is a table illustrating an example of properties of members used for manufacturing the semiconductor device 1 according to the second embodiment. FIG. 15 illustrates refractive indexes n and extinction coefficients k of four kinds of media that can be used for manufacturing the semiconductor device 1. (1), (2), and (3) of FIG. 15 correspond to silicon (Si), a silicon oxide film (SiO₂), and polysilicon (poly-Si), respectively. (4) of FIG. 15 corresponds to a homogeneous medium including a combination of a medium (2) and a medium (3) ((2)+(3)). Specifically, in the homogeneous medium of the present example, the silicon oxide film corresponds to the light absorption layer 120, and the polysilicon corresponds to the antireflection layer 110a.

As illustrated in (1) of FIG. 15, a refractive index n of the silicon is 3.42, and an extinction coefficient k of the silicon is 0. As illustrated in (2) of FIG. 15, a refractive index n of the silicon oxide film is 1.63, and an extinction coefficient k of the silicon oxide film is 2.31. As illustrated in (3) of FIG. 15, a refractive index n of the polysilicon is 3.66, and an extinction coefficient k of the polysilicon is 0. A property of a homogeneous medium illustrated in (4) of FIG. 15 correspond to a property in a case where the thickness of the light absorption layer 120 (oxide film thickness) is 0.5 μm, and the main pitch P1, the sub-pitch P2, the line width, the space width, and the pattern height of the antireflection layer 110a are 0.9 μm, 0.3 μm, 0.225 μm, 0.075 μm, and 0.2 μm, respectively. In the present example, a refractive index n of the homogeneous medium is 3.08, and an extinction coefficient k of the homogeneous medium is 0.31. As described above, the refractive index of the homogeneous medium can be adjusted to a value between the silicon used as the first wafer W1 and the silicon oxide film used as the light absorption layer 120.

<2-2> Method of Manufacturing

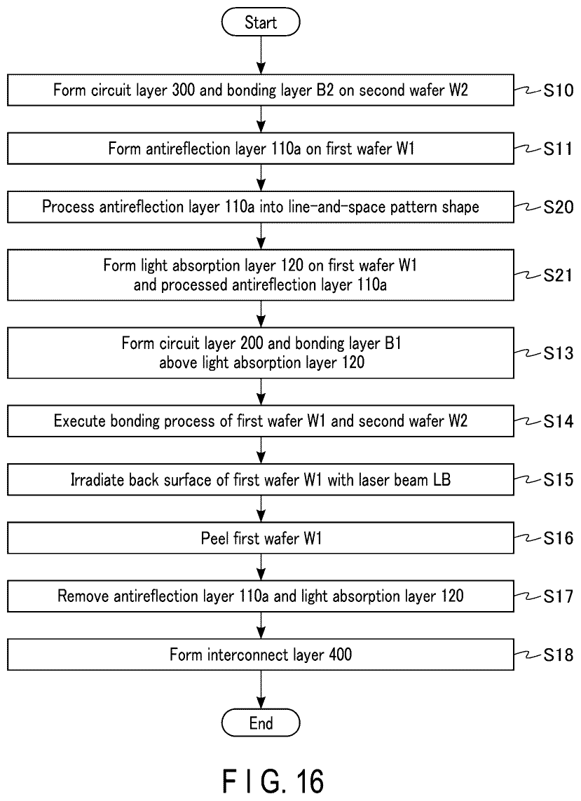

FIG. 16 is a flowchart illustrating an example

of a method of manufacturing the semiconductor device 1 according to the second embodiment. As illustrated in FIG. 16, the method of manufacturing the semiconductor device 1 according to the second embodiment has a configuration in which the processing of S12 is replaced with the processing of S20 and S21 in the method of manufacturing the semiconductor device 1 according to the first embodiment illustrated in FIG. 5.

Specifically, first, similarly to the first embodiment, the processing of S10 and S11 is sequentially executed. In other words, a circuit layer 300 and a bonding layer B2 are formed on the second wafer W2 (S10). The antireflection layer 110a is formed on the first wafer W1 (S11).

Then, the antireflection layer 110a is processed into a line-and-space pattern shape (S20). In the processing of S20, the antireflection layer 110a is processed into a shape of the antireflection layer 110a illustrated in FIG. 12 or 13. For processing of the antireflection layer 110a, for example, a combination of photolithography processing and etching processing is used. Then, the light absorption layer 120 is formed on the first wafer W1 and the processed antireflection layer 110a (S21). In the processing of S21, the light absorption layer 120 is formed so that a portion from which the antireflection layer 110a is removed in the processing of S20 is filled up. After the processing of S21, the flattening processing of an upper surface of the light absorption layer 120 may be executed.

Thereafter, similarly to the first embodiment, the processing of S13 to S18 are sequentially executed to form a structure of the semiconductor device 1 illustrated in FIG. 3. Note that the processing of S10 and the processing of S11, S20, S21, and S13 may be executed in parallel, or the order of these processing processes may be switched. In the second embodiment, a method of optimizing design parameters of the peeling layer 100a similar to that in the first embodiment may be used. In a simulation of a fluctuation range and an average value of the light absorption rate in the second embodiment, a pitch, a sub-pitch, a line width, and the like of a line-and-space pattern may be used as variables. In the processing of each of S11, S20, and S12, processing parameters may be adjusted so that the processing parameters approach the oxide film thickness H0, the antireflection layer thickness H1, and the like based on a value of wafer thickness measured in advance. Other methods of manufacturing the semiconductor device 1 according to the second embodiment are similar to the method of manufacturing the semiconductor device 1 according to the first embodiment.

### <2-3> Effects of Second Embodiment

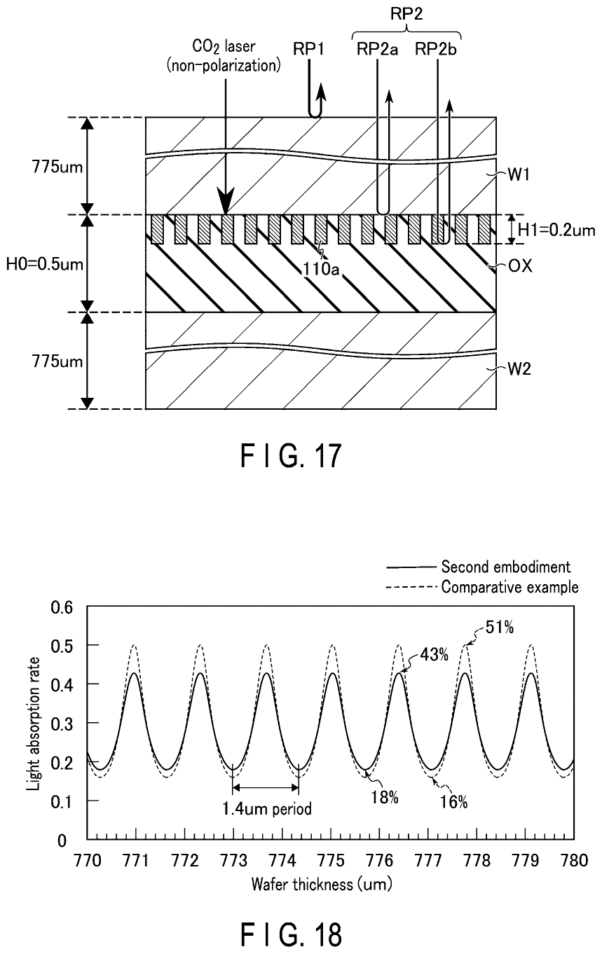

FIG. 17 is a schematic diagram illustrating an example of a structure of an object to be irradiated with a laser beam, an incident laser beam, and generated reflected light beams in the semiconductor device 1 according to the second embodiment. FIG. 17 schematically illustrates a structure in which the antireflection layer 110 is replaced with the antireflection layer 110a and a CO₂ laser of non-polarization in the structure used in the first embodiment illustrated in FIG. 7, and FIG. 17 illustrates coordinate axes based on the second wafer W2. In the present example, the same configuration as a configuration of the homogeneous medium illustrated in FIG. 15 is provided at the height at which the antireflection layer 110a is provided. Similarly to the first embodiment, a reflected light beam RP2a is generated by a boundary between the homogeneous medium and the first wafer W1. In addition, similarly to the first embodiment, a reflected light beam RP2b is generated by a boundary between the homogeneous medium and a silicon oxide film OX. As a result, in the second embodiment, the fluctuation range due to interference by reflected light beams RP1 and RP2 can be reduced as compared with the comparative example, similarly to the first embodiment.

FIG. 18 is a graph illustrating a result of an optical simulation regarding fluctuations in a light absorption rate of the peeling layer 100a in each of the second embodiment and the comparative example. A horizontal axis illustrates the wafer thickness (μm). A vertical axis illustrates the light absorption rate. A broken line corresponds to the light absorption rate in a configuration of the comparative example illustrated in FIG. 9. A solid line illustrates the light absorption rate in a configuration of the second embodiment illustrated in FIG. 17. As illustrated in FIG. 18, the light absorption rate in the second embodiment fluctuates at a period of 1.4 μm. Then, the light absorption rate in the second embodiment fluctuates in a range of 18% to 43%. In other words, the fluctuation range of the light absorption rate in the second embodiment is about 25% and is narrower than 35% that is the fluctuation range of the light absorption rate in the comparative example.

As described above, in the method of manufacturing the semiconductor device 1 according to the second embodiment, the fluctuations in the light absorption rate based on fluctuations in the wafer thickness can be suppressed in a peeling process of the first wafer W1 using laser peeling, as compared with the first embodiment. In other words, the method of manufacturing the semiconductor device 1 according to the second embodiment can suppress fluctuations in energy absorbed by the peeling layer 100a in the laser peeling and can achieve a stable peeling process, as compared with the first embodiment. As a result, the method of manufacturing the semiconductor device 1 according to the second embodiment can improve a yield of a manufacturing process of a semiconductor device that reuses the first wafer W1, and the method can suppress a manufacturing cost of the semiconductor device.

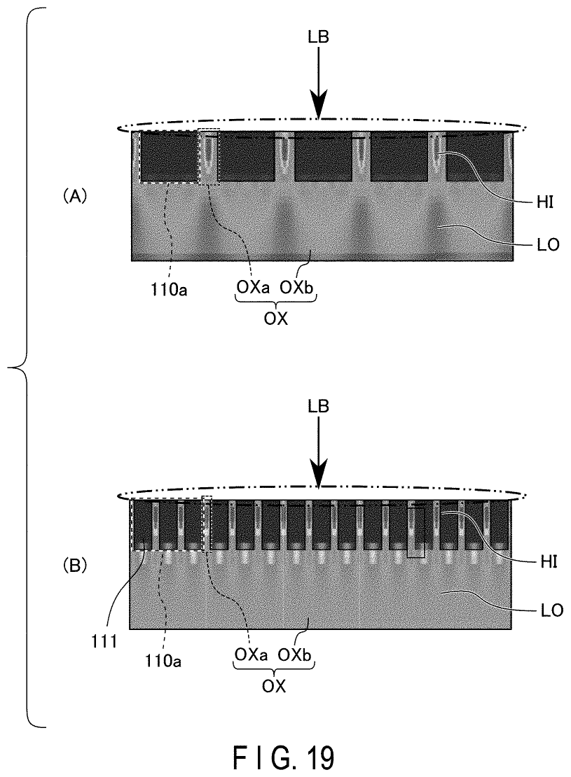

FIG. 19 is a schematic view illustrating an example of a light absorption rate distribution of the peeling layer 100a in the peeling process of the second embodiment. FIG. 19A illustrates a structure of the peeling layer 100a and a distribution of heat generated by irradiation with the laser beam LB in a case where the sub-pattern 111 is not provided. FIG. 19B illustrates a structure of the peeling layer 100a and a distribution of a light absorption rate in a case where the laser beam LB is emitted in a case where the sub-pattern 111 is provided. A silicon oxide film OXa is a portion of the silicon oxide film OX corresponding to the above-described homogeneous medium. A silicon oxide film OXb is a portion corresponding to the light absorption layer 120. “HI” illustrates a portion having a high light absorption rate. “LO” illustrates a portion having a low light absorption rate. As illustrated in FIG. 19, the light absorption rate in a case where the laser beam LB is emitted can be more uniform in a case where the sub-pattern 111 is provided than a case where the sub-pattern 111 is not provided. By introducing the sub-pattern 111, the feasibility of an effective medium approximation and the adjustment of the equivalent refractive index can be controlled independently.

### <3> Third Embodiment

A third embodiment relates to a method of manufacturing a semiconductor device 1 that suppresses fluctuations in a light absorption rate with a combination of a peeling layer 100a similar to the peeling layer 100a of the second embodiment and polarization of a laser beam LB. Hereinafter, details of the third embodiment will be described mainly on differences from the first and second embodiments.

### <3-1> Configuration

A configuration of the semiconductor device 1 according to the third embodiment is similar to the configuration of the semiconductor device 1 according to the second embodiment. In addition, similarly, a structure of the peeling layer 100a formed in a manufacturing process of the semiconductor device 1 according to the third embodiment is also similar to the structure of the peeling layer 100a formed in the manufacturing process of the semiconductor device 1 according to the second embodiment.

### <3-2> Method of Manufacturing

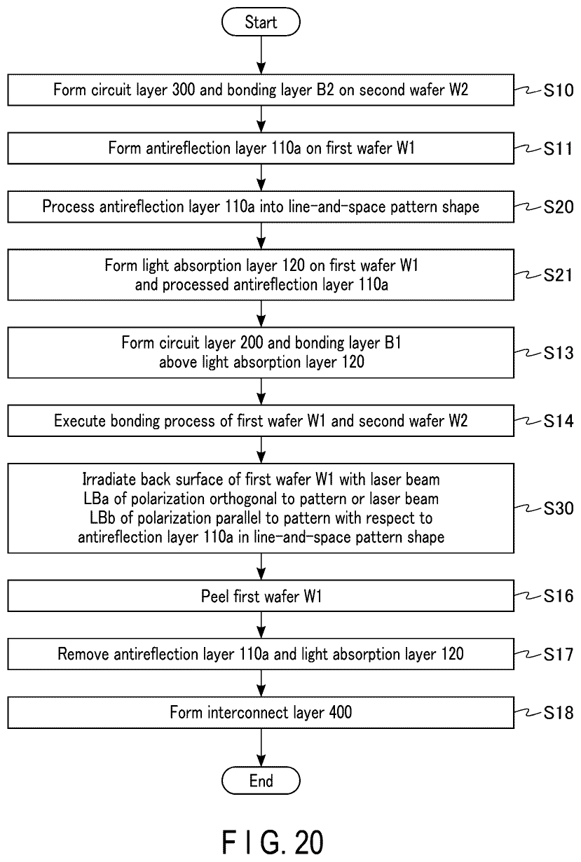

FIG. 20 is a flowchart illustrating an example

of the method of manufacturing the semiconductor device 1 according to the third embodiment. As illustrated in FIG. 20, the method of manufacturing the semiconductor device 1 according to the third embodiment has a configuration in which the processing of S15 is replaced with the processing of S30 in the method of manufacturing the semiconductor device 1 according to the second embodiment illustrated in FIG. 16.

Specifically, first, similarly to the second embodiment, the processing of S10, S11, S20, S21, S13, and S14 is sequentially executed. In other words, a circuit layer 300 and a bonding layer B2 are formed on the second wafer W2 (S10). The antireflection layer 110a is formed on the first wafer W1 (S11). The antireflection layer 110a is processed into a line-and-space pattern shape (S20). A light absorption layer 120 is formed on the first wafer W1 and the processed antireflection layer 110a (S21). Next, a circuit layer 200 and a bonding layer B1 are formed above the light absorption layer 120 (S13). The bonding process of the first wafer W1 and the second wafer W2 is executed (S14).

Then, a back surface of the first wafer W1 is irradiated with a laser beam LBa of polarization orthogonal to a pattern or a laser beam LBb of polarization parallel to the pattern with respect to the antireflection layer 110a in the line-and-space pattern shape (S30). The polarization orthogonal to the pattern is polarization orthogonal to a line-and-space pattern. The polarization parallel to the pattern is polarization parallel to the line-and-space pattern. In the processing of S30, the laser beam LBa or LBb passes through the first wafer W1 and reaches the peeling layer 100a including the antireflection layer 110a and the light absorption layer 120. At this time, the light absorption layer 120 absorbs the laser beam LBa or LBb at a light absorption rate corresponding to an interference effect of a reflected light beam at the back surface of the first wafer W1 (interface with air), a reflected light beam at an interface between the first wafer W1 and the peeling layer 100a (that is, an upper end portion of the antireflection layer 110a), and a reflected light beam at a lower end portion of the antireflection layer 110a. Then, the light absorption layer 120 generates heat by absorbing the laser beam LBa or LBb, and a vicinity of a portion in contact with a peeling surface of the first wafer W1 is plastically deformed based on the heat generated in the light absorption layer 120. Then, an irradiation position of the laser beam LBa or LBb is changed, and the back surface of the first wafer W1 is irradiated with the laser beam LBa or LBb at a predetermined interval.

Thereafter, similarly to the first embodiment, the processing of S16 to S18 is sequentially executed to form a structure of the semiconductor device 1 illustrated in FIG. 3. Note that the processing of S10 and the processing of S10, S11, S20, S21, S13, and S14 may be executed in parallel, or the order of these processing steps may be switched. In the processing of S30, the laser beam LBa and LBb may be selectively used according to a layout of the antireflection layer 110a in the peeling layer 100a. The method of manufacturing the semiconductor device 1 according to the third embodiment includes a step (S30) of controlling the polarization of the laser beam LB so that polarization of the laser beam

LB is polarization parallel to the line-and-space pattern of the antireflection layer 110a or polarization orthogonal to the line-and-space pattern of the antireflection layer 110a in the case of irradiating the back surface of the first wafer W1 with the laser beam LB. Other methods of manufacturing the semiconductor device 1 according to the third embodiment are similar to the method of manufacturing the semiconductor device 1 according to the second embodiment.

### <3-3> Effects of Third Embodiment

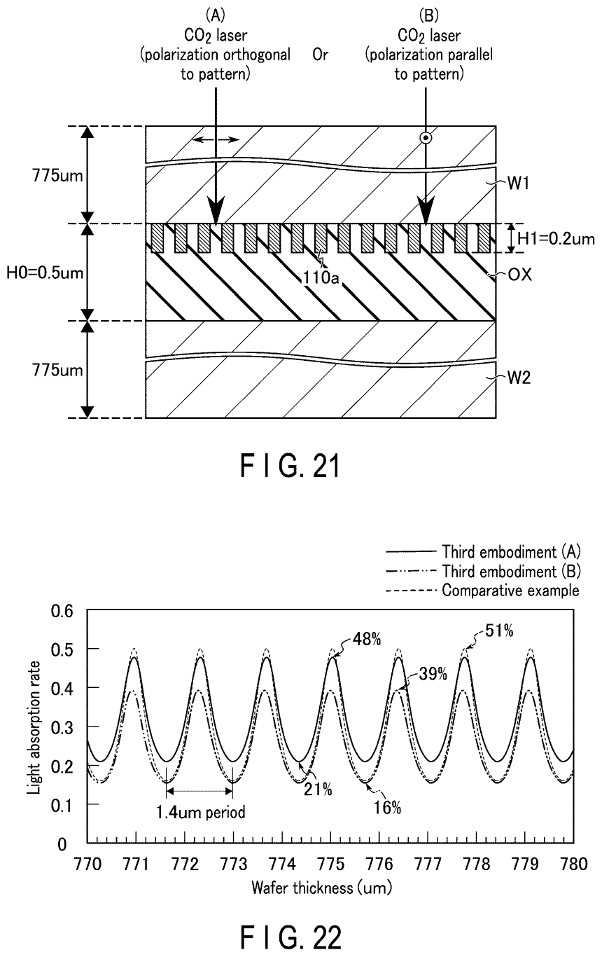

FIG. 21 is a schematic diagram illustrating an example of a structure of an object to be irradiated with a laser beam in the semiconductor device 1 according to the third embodiment. FIG. 21 schematically illustrates the example of the structure of the object to be irradiated with the laser beam in the semiconductor device 1 according to the second embodiment illustrated in FIG. 17, a CO₂ laser of polarization orthogonal to the pattern ((A) of FIG. 21) , and a CO₂ laser of polarization parallel to the pattern ((B) of FIG. 21). In the present example, similarly to the second embodiment, a reflected light beam RP2a (not illustrated) is generated by a boundary between a homogeneous medium and a first wafer W1. In addition, similarly to the second embodiment, a reflected light beam RP2b (not illustrated) is generated by a boundary between the homogeneous medium and a silicon oxide film OX. As a result, in the third embodiment, similarly to the second embodiment, a fluctuation range due to interference by reflected light beams RP1 and RP2 can be reduced as compared with the comparative example. Furthermore, in the third embodiment, polarization orthogonal or parallel to the pattern is used.

FIG. 22 is a graph illustrating a result of an optical simulation regarding fluctuations in a light absorption rate of the peeling layer 100a in each of the third embodiment and the comparative example. A horizontal axis illustrates the wafer thickness (μm). A vertical axis illustrates fluctuations in the light absorption rate. A broken line corresponds to the light absorption rate in a configuration of the comparative example illustrated in FIG. 9. A solid line illustrates fluctuations in the light absorption rate in a case where the CO₂ laser of polarization orthogonal to the pattern is used in a configuration of the third embodiment illustrated in FIG. 21 (third embodiment (A)). A two-dot-dash line illustrates fluctuations in the light absorption rate in a case where the CO₂ laser of polarization parallel to the pattern is used in the configuration of the third embodiment illustrated in FIG. 21 (third embodiment (B)).

As illustrated in FIG. 22, the light absorption rate in the third embodiment fluctuates at a period of 1.4 μm in both the polarization orthogonal to the pattern and the polarization parallel to the pattern. The light absorption rate in the third embodiment fluctuates in a range of 21% to 48% in a case where the polarization orthogonal to the pattern is used. In addition, the light absorption rate in the third embodiment fluctuates in a range of 16% to 39% in a case where the polarization parallel to the pattern is used. That is, the fluctuation range of the light absorption rate in the third embodiment is about 27% in a case where the polarization orthogonal to the pattern is used and about 23% in a case where the polarization parallel to the pattern is used. As described above, in each of the case where the polarization orthogonal to the pattern is used and the case where the polarization parallel to the pattern is used, the fluctuation range of the light absorption rate is narrower than 35% that is the fluctuation range of the light absorption rate in the comparative example. In addition, in a case where the polarization orthogonal to the pattern is used, the fluctuation range of the light absorption rate is larger than a case of the non-polarization (second embodiment). Meanwhile, in a case where the polarization orthogonal to the pattern is used, a lower limit of the light absorption rate is higher than the case of the non-polarization. Therefore, the use of the polarization orthogonal to the pattern can suppress the fluctuation range of the light absorption rate while keeping an average value of the light absorption rate high, as compared with the second embodiment.

As described above, the method of manufacturing the semiconductor device 1 according to the third embodiment may be able to suppress fluctuations in the light absorption rate based on fluctuations in the wafer thickness in a peeling process of the first wafer W1 using laser peeling, as compared with the case of the non-polarization. In other words, the method of manufacturing the semiconductor device 1 according to the third embodiment can suppress fluctuations in energy absorbed by the peeling layer 100a in the laser peeling by using appropriate polarization and can achieve a stable peeling process, as compared with the second embodiment. As a result, the method of manufacturing the semiconductor device 1 according to the third embodiment can improve a yield of a manufacturing process of a semiconductor device that reuses the first wafer W1, and the method can suppress a manufacturing cost of the semiconductor device.

### <4> Fourth Embodiment

A fourth embodiment is a specific example of a semiconductor device 1 to which any of the first to third embodiments is applied. Hereinafter, as the fourth embodiment, a case where the above-described embodiment and a memory device capable of storing data in a non-volatile manner are combined will be described.

### <4-1> Configuration

### <4-1-1> Overall Configuration of Semiconductor Device 1a

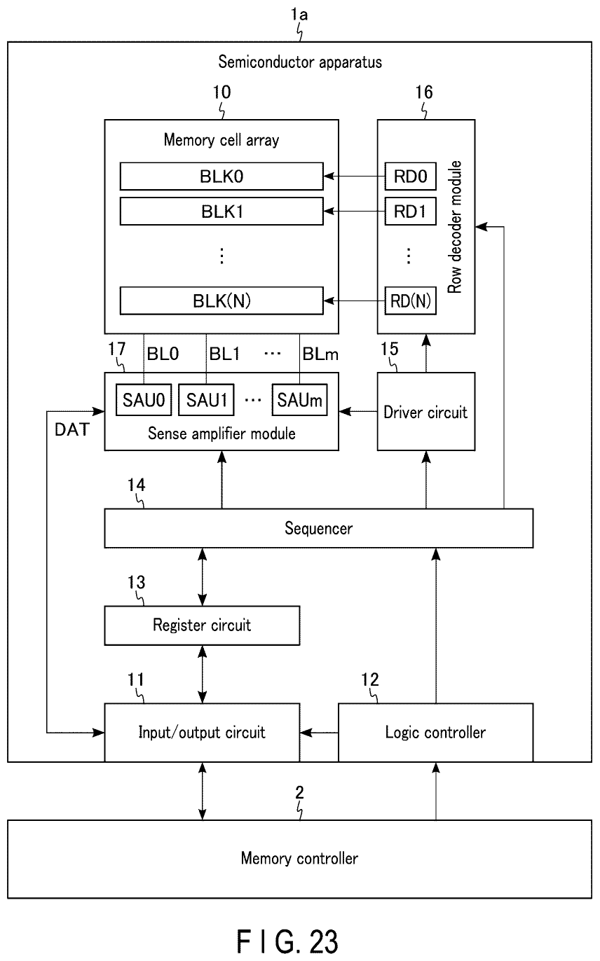

FIG. 23 is a block diagram illustrating an example of an overall configuration of a semiconductor device 1a according to a fourth embodiment. As illustrated in FIG. 23, the semiconductor device 1a is a memory device such as an NAND flash memory. The semiconductor device 1a is controlled by an external memory controller 2. The semiconductor device 1a includes, for example, a memory cell array 10, an input/output circuit 11, a logic controller 12, a register circuit 13, a sequencer 14, a driver circuit 15, a row decoder module 16, and a sense amplifier module 17.

The memory cell array 10 includes a plurality of blocks BLK0 to BLKn (“n” is an integer of 1 or more). A block BLK is a set of a plurality of memory cells. The block BLK corresponds to, for example, a unit of erasing data. The block BLK includes a plurality of pages. The page corresponds to a unit in which read and write of data are executed. Although not illustrated, the memory cell array 10 is provided with a plurality of bit lines BL0 to BLm (“m” is an integer of 1 or more) and a plurality of word lines WL. Each memory cell is associated with, for example, one bit line BL and one word line WL.

The input/output circuit 11 is an interface circuit that controls transmission and reception of an input/output signal from and to the memory controller 2. The input/output signal includes, for example, data DAT, status information, address information, a command, and the like. The input/output circuit 11 can input and output the data DAT from and to the sense amplifier module 17 and from and to the memory controller 2. The input/output circuit 11 can output the status information transferred from the register circuit 13 to the memory controller 2. The input/output circuit 11 can output each of the address information and the command transferred from the memory controller 2 to the register circuit 13.

The logic controller 12 controls each of the input/output circuit 11 and the sequencer 14 based on a control signal input from the memory controller 2. For example, the logic controller 12 controls the sequencer 14 to enable the semiconductor device 1a. The logic controller 12 notifies the input/output circuit 11 that the input/output signal received by the input/output circuit 11 is a command, address information, or the like. The logic controller 12 orders the input/output circuit 11 to input or output the input/output signal.

The register circuit 13 temporarily stores the status information, the address information, and the command. The status information is updated based on the control of the sequencer 14 and transferred to the input/output circuit 11. The address information includes a block address, a page address, a column address, and the like. The command includes an order related to various operations of the semiconductor device 1a.

The sequencer 14 controls the entire operation of the semiconductor device 1a. The sequencer 14 executes a read operation, a write operation, an erase operation, and the like based on the command and the address information stored in the register circuit 13.

The driver circuit 15 generates a voltage used for the read operation, the write operation, the erase operation, and the like. Then, the driver circuit 15 supplies the generated voltage to the row decoder module 16, the sense amplifier module 17, and the like.

The row decoder module 16 is a circuit used for selecting the block BLK to be operated and transferring a voltage to an interconnect such as the word line WL. The row decoder module 16 includes a plurality of row decoders RD0 to RDn. The row decoders RD0 to RDn are associated with the blocks BLK0 to BLKn, respectively. Each row decoder RD is used for selecting the block BLK.

The sense amplifier module 17 is a circuit used for transferring a voltage to each bit line BL and reading data. The sense amplifier module 17 includes a plurality of sense amplifier units SAU0 to SAUm. The sense amplifier units SAU0 to SAUm are associated with the plurality of bit lines BL0 to BLm, respectively. Each sense amplifier unit SAU includes a sense amplifier for determining data and a latch circuit for temporarily holding data.

A circuit layer 200 in the semiconductor device 1a includes, for example, the memory cell array 10. A circuit layer 300 in the semiconductor device 1a includes, for example, the input/output circuit 11, the logic controller 12, the register circuit 13, the sequencer 14, the driver circuit 15, the row decoder module 16, and the sense amplifier module 17. Note that a combination of the semiconductor device 1a and the memory controller 2 may constitute one semiconductor device. An example of such a semiconductor device include a memory card such as an SDTM card, a solid state drive (SSD), and the like.

### <4-1-2> Circuit Configuration of Memory Cell Array 10

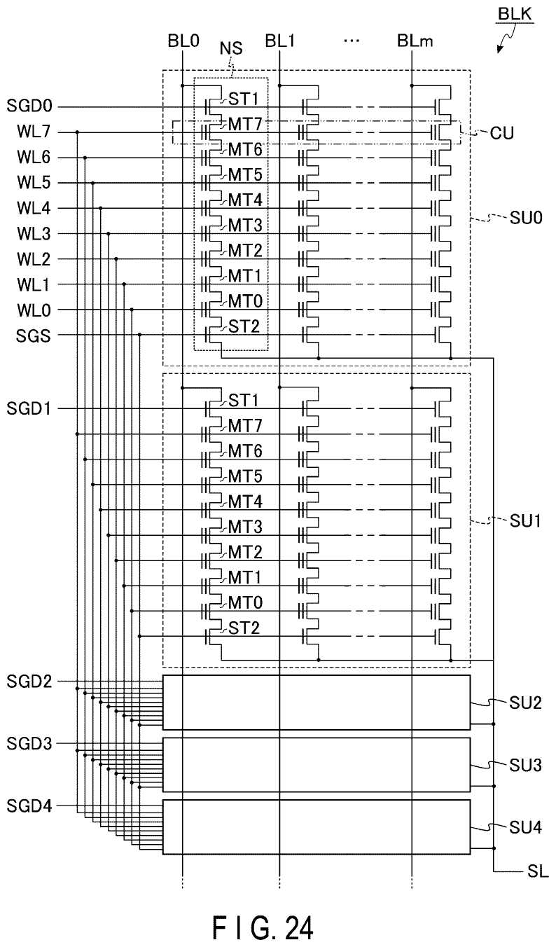

FIG. 24 is a circuit diagram illustrating an example of a circuit configuration of the memory cell array 10 included in the semiconductor device 1a according to the fourth embodiment. FIG. 24 illustrates one block BLK out of the plurality of blocks BLK included in the memory cell array 10. As illustrated in FIG. 24, the block BLK includes, for example, five string units SU0 to SU4. Select gate lines SGD0 to SGD4 and SGS and word lines WL0 to WL7 are provided for each block BLK.

The bit lines BL0 to BLm and a source line SL are shared by the plurality of blocks BLK.

Each string unit SU includes a plurality of NAND strings NS. Each of the plurality of NAND strings NS is associated with each of the bit lines BL0 to BLm. That is, each bit line BL is shared by the NAND string NS to which the same column address among the plurality of blocks BLK is allocated. Each NAND string NS is connected between the associated bit line BL and the source line SL. Each NAND string NS includes, for example, memory cell transistors MT0 to MT7 and select transistors ST1 and ST2. Each memory cell transistor MT is a memory cell including a control gate and a charge storage layer and holds (stores) data in a nonvolatile manner. Each of the select transistors ST1 and ST2 is used for selecting the string unit SU.

In each NAND string NS, the select transistor ST1, the memory cell transistors MT0 to MT7, and the select transistor ST2 are connected in series in this order. Specifically, a drain of the select transistor ST1 is connected to the associated bit line BL, and a source of the select transistor ST1 is connected to a drain of the memory cell transistor MT7. A drain of the select transistor ST2 is connected to a source of the memory cell transistor MT0, and a source of the select transistor ST2 is connected to the source line SL. The memory cell transistors MT0 to MT7 are connected in series between the select transistors ST1 and ST2.

The select gate lines SGD0 to SGD4 are associated with the string units SU0 to SU4, respectively. Each select gate line SGD is connected to a gate of each of a plurality of select transistors ST1 included in the associated string unit SU. The select gate line SGS is connected to a gate of each of a plurality of select transistors ST2 included in an associated block BLK. The word lines WL0 to WL7 are connected to the control gates of the memory cell transistors MT0 to MT7, respectively.

A set of a plurality of memory cell transistors MT connected to a common word line WL in the same string unit SU is referred to as, for example, a “cell unit CU”. For example, a storage capacity of the cell unit CU in a case where each memory cell transistor MT stores 1-bit data is defined as “1-page data”. The cell unit CU can have a storage capacity of 2-page or more data according to the number of bits of data stored in each memory cell transistor MT.

Note that the circuit configuration of the memory cell array 10 included in the semiconductor device 1a may be another configuration. For example, the number of string units SU included in each block BLK, the number of memory cell transistors MT included in each NAND string NS, the number of select transistors ST1 included in each NAND string NS, and the number of select transistors ST2 included in each NAND string NS can be designed to be any numbers.

### <4-1-3> Structure of Semiconductor Device 1a

Hereinafter, a structure of the semiconductor device 1a according to the fourth embodiment will be described.

### (1: Planar Layout of Memory Cell Array 10)

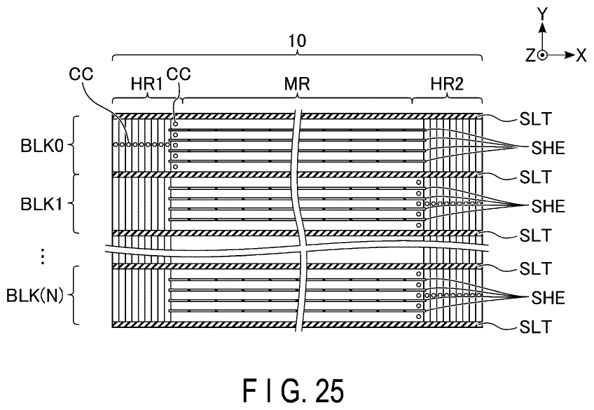

FIG. 25 is a schematic diagram illustrating an example of a planar layout of the memory cell array 10 included in the semiconductor device 1a according to the fourth embodiment. As illustrated in FIG. 25, the memory cell array 10 includes, for example, a memory region MR and hookup regions HR1 and HR2. The memory region MR includes a plurality of NAND strings NS. The memory region MR is sandwiched in an X direction by the hookup regions HR1 and HR2. Each of the hookup regions HR1 and HR2 is a region used for connection between a stack interconnect (for example, the word line WL and the select gate lines SGD and SGS) and the row decoder module 16. In addition, the memory cell array 10 includes a plurality of slits SLT, a plurality of slits SHE, and a plurality of contacts CC.

Each slit SLT has a portion provided while extending along the X direction and crosses the hookup region HR1, the memory region MR, and the hookup region HR2 along the X direction. The plurality of slits SLT is arranged in a Y direction. Each slit SLT divides interconnects (for example, the word lines WL0 to WL7 and the select gate lines SGD and SGS) adjacent to each other via the slit SLT. In each slit SLT, a conductor in which a spacer of an insulator is provided on a side wall may be disposed while being insulated from these interconnects or an insulator may be embedded. In the memory cell array 10, each region divided along the Y direction by the slit SLT corresponds to one block BLK.

Each slit SHE has a portion provided while extending along the X direction and crosses the memory region MR along the X direction. The plurality of slits SHE is arranged in the Y direction. In the present example, four slits SHE are disposed between each set of two slits SLT adjacent to each other in the Y direction. Each slit SHE has, for example, a structure in which an insulator is embedded. Each slit SHE divides interconnects adjacent to each other via the slit SHE. It suffices that the slit SHE divides at least the select gate line SGD. In the memory cell array 10, each region divided along the Y direction by the slits SLT and SHE corresponds to one string unit SU.

Each end of the stack interconnect (for example, the select gate line SGS, the word lines WL0 to WL7, and the select gate line SGD) included in the memory cell array 10 has a terrace portion in each of the hookup regions HR1 and HR2. The terrace portion corresponds to a portion that does not overlap the interconnect layer (conductive layer) provided on a side of the bit line BL. A structure formed by a plurality of terrace portions is similar to a step, a terrace, rimstone, or the like. In the present example, a staircase structure having a step in the X direction is formed by an end of the select gate line SGS, an end of each of the word lines WL0 to WL7, and an end of the select gate line SGD.

The contact CC connected to the stack interconnect is connected to the terrace portion of at least one of the hookup regions HR1 and HR2. For example, the stack interconnect of the even-numbered block BLK (BLK0, BLK2, . . . ) is connected to the contact CC provided in the hookup region HR1. The stack interconnect of the odd-numbered block BLK (BLK1, BLK3, . . . ) is connected to the contact CC provided in the hookup region HR2.

Note that the planar layout of the memory cell array 10 included in the semiconductor device 1a may be another layout. For example, the number of slits SHE disposed between two slits SLT adjacent to each other can be designed to be any number. The number of string units SU included in each block BLK can be changed based on the number of slits SHE disposed between two slits SLT adjacent to each other. The disposition of the contact CC connected to the stack interconnect can be appropriately changed. The semiconductor device 1a may have a structure in which the terrace portion of each hookup region HR is omitted. In this case, the contact CC connected to a certain interconnect layer of the stack interconnect penetrates an upper conductive layer and is provided while being separated (insulated). The hookup region HR may be disposed so as to divide the memory region MR in the X direction.

### (2: Planar Layout of Memory Region MR)

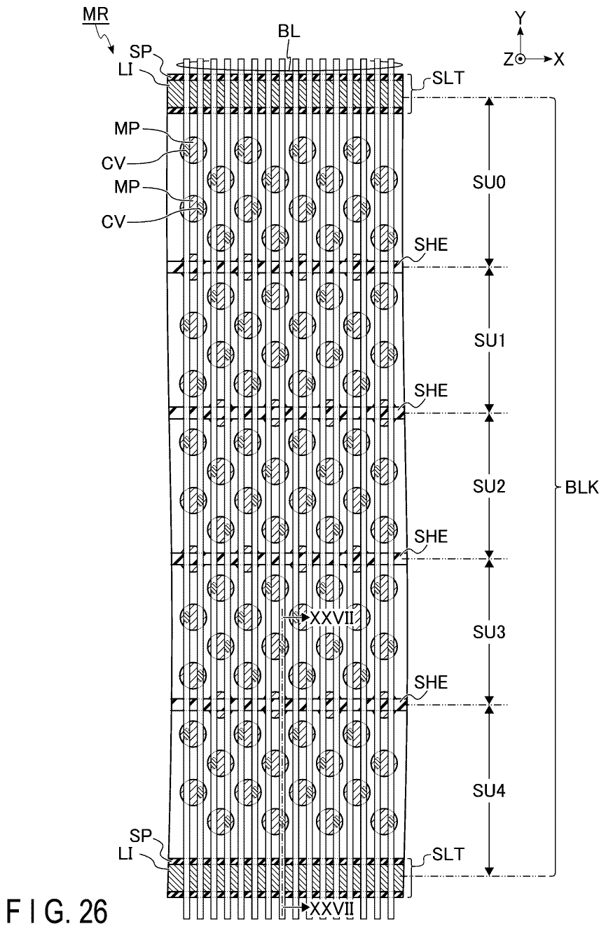

FIG. 26 is a plan view illustrating an example of a planar layout of the memory region MR of the semiconductor device 1a according to the fourth embodiment. FIG. 26 illustrates a region including one block BLK (that is, the string units SU0 to SU4). As illustrated in FIG. 26, in the memory region MR, the memory cell array 10 includes, for example, a plurality of memory pillars MP, a plurality of contacts CV, and a plurality of bit lines BL. Each slit SLT includes a contact LI and a spacer SP.

Each memory pillar MP functions as one NAND string NS. The plurality of memory pillars MP is disposed, for example, in a staggered manner with 24 rows in a region between two slits SLT adjacent to each other. In the present example, one slit SHE is disposed while overlapping each of the memory pillar MP in the fifth row, the memory pillar MP in the 10th row, the memory pillar MP in the 15th row, and the memory pillar MP in the 20th row if counted from the upper side of the paper surface.

Each of the bit lines BL has a portion provided while extending in the Y direction. The plurality of bit lines BL is arranged in the X direction. Each bit line BL is disposed so as to overlap at least one memory pillar MP for each string unit SU. In the present example, two bit lines BL are disposed while overlapping one memory pillar MP. The memory pillar MP is electrically connected to one bit line BL via the contact CV.

The contact LI is a conductor having a portion provided while extending in the X direction. The spacer SP is an insulator provided on a side surface of the contact LI. The contact LI is sandwiched between the spacers SP. The spacer SP separates and insulates between the contact LI and conductors (for example, word lines WL0 to WL7 and select gate lines SGD and SGS) adjacent to the contact LI in the Y direction. The spacer SP is, for example, an oxide film.

(3: Cross-Sectional Structure of First Wafer W1)

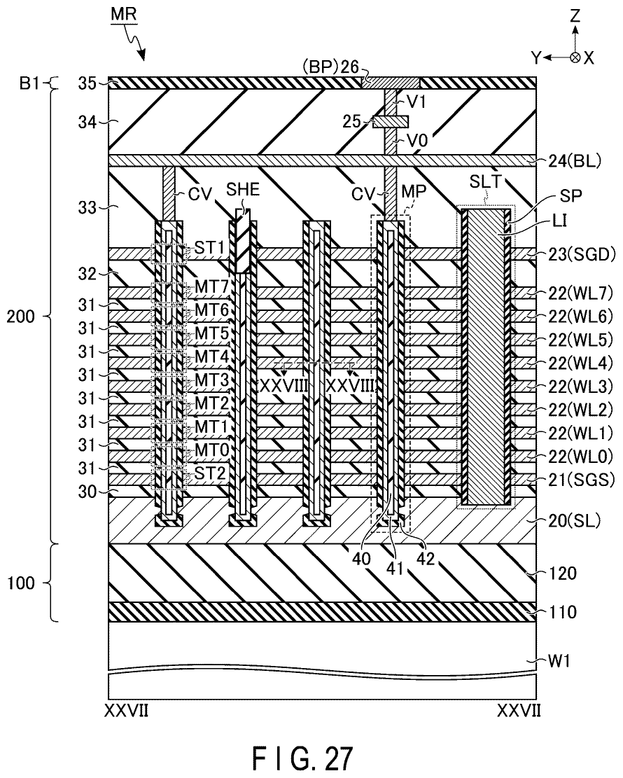

FIG. 27 is a cross-sectional view taken along line XXVII-XXVII of FIG. 26 and illustrating an example of a cross-sectional structure of a first wafer W1 used for manufacturing the semiconductor device 1a according to the fourth embodiment. FIG. 27 illustrates an example of a structure in the memory region MR of the memory cell array 10 formed on the first wafer W1 before the first wafer W1 is bonded to a second wafer W2, and FIG. 27 displays coordinate axes based on the first wafer W1. As illustrated in FIG. 27, the circuit layer 200 includes, for example, conductive layers 20 to 25, insulating layers 30 to 35, and contacts V0 and V1. A bonding layer B1 includes, for example, a conductive layer 26 and an insulating layer 35.

The conductive layer 20 is provided, for example, on a light absorption layer 120. The insulating layer 30 is provided on the conductive layer 20. The conductive layer 21 and the insulating layer 31 are alternately provided on the insulating layer 30. The insulating layer 32 is provided on the conductive layer 22 that is the uppermost layer. The conductive layer 23 is provided on the insulating layer 32. The insulating layer 33 is provided on the conductive layer 23. The conductive layer 24 is provided on the insulating layer 33. The contact V0 is provided on the conductive layer 24. The conductive layer 25 is provided on the contact V0. The contact V1 is provided on the conductive layer 25. The conductive layer 26 is provided on the contact V1. The contact V0, the conductive layer 25, and the contact VI are covered with the insulating layer 34. The insulating layer 34 can include a plurality of insulating layers. The insulating layer 35 is provided on the insulating layer 34.

Each of the conductive layers 21, 22, and 23 is formed, for example, in a plate shape extending along an XY plane. The conductive layer 24 is formed, for example, in a line shape extending in the Y direction. The conductive layers 20, 21, and 23 are used as the source line SL, the select gate line SGS, and the select gate line SGD, respectively. A plurality of conductive layers 22 is used in order from the bottom as the word lines WL0 to WL7. A portion where the memory pillar MP intersects the conductive layer 21 functions as the select transistor ST2. A portion where the memory pillar MP intersects the conductive layer 22 functions as the memory cell transistor MT. A portion where the memory pillar MP intersects the conductive layer 23 functions as the select transistor ST1. The conductive layer 24 is used as the bit line BL. The conductive layers 24 and 25 are connected via the contact V0. The conductive layer 25 and the conductive layer 26 are connected via the contact V1. The conductive layer 26 corresponds to the bonding pad BP. The conductive layer 26 includes, for example, copper.

The slit SLT has a plate-like portion formed in a plate shape extending along an XZ plane and divides the insulating layers 30 to 32 and the conductive layers 21 to 23. A bottom portion of the slit SLT is in contact with the conductive layer 20. The contact LI in the slit SLT is electrically connected to the conductive layer 20. In addition, the spacer SP in the slit SLT separates and insulates between each of the conductive layers 21 to 23 and the contact LI.

Each memory pillar MP is provided while extending along a Z direction and penetrates the insulating layer 30 to 32 and the conductive layer 21 to 23. Each memory pillar MP includes, for example, a core member 40, a semiconductor layer 41, and a stacked film 42. The core member 40 is an insulator provided while extending along the Z direction. The semiconductor layer 41 covers the core member 40. The semiconductor layer 41 is in contact with the conductive layer 20 via a side surface of the memory pillar MP. The stacked film 42 covers a side surface of the semiconductor layer 41 except for a portion where the semiconductor layer 41 and the conductive layer 20 are in contact with each other. The contact CV is provided on the semiconductor layer 41. The semiconductor layer 41 and the conductive layer 24 are connected via the contact CV.

### (4: Cross-Sectional Structure of Memory Pillar MP)

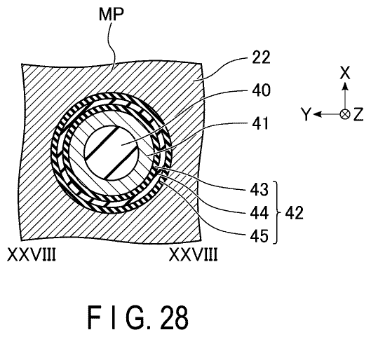

FIG. 28 is a cross-sectional view taken along line XXVIII-XXVIII in FIG. 27 and illustrating an example of a cross-sectional structure of the memory pillar MP in the semiconductor device 1a according to the fourth embodiment. FIG. 28 illustrates a cross section including the memory pillar MP and the conductive layer 22 and parallel to a surface of the source line SL. As illustrated in FIG. 28, the stacked film 42 includes a tunnel insulating film 43, an insulating film 44, and a block insulating film 45.

The core member 40 is provided, for example, in a central portion of the memory pillar MP. The semiconductor layer 41 surrounds a side surface of the core member 40. The tunnel insulating film 43 surrounds the side surface of the semiconductor layer 41. The insulating film 44 surrounds a side surface of the tunnel insulating film 43. The block insulating film 45 surrounds a side surface of the insulating film 44. The conductive layer 22 surrounds the side surface of the block insulating film 45. The semiconductor layer 41 is used as a channel (current path) of the memory cell transistors MT0 to MT7 and the select transistors ST1 and ST2. Each of the tunnel insulating film 43 and the block insulating film 45 includes, for example, a silicon oxide film. The insulating film 44 is used as the charge storage layer of the memory cell transistor MT and includes, for example, a silicon nitride film. As a result, each memory pillar MP functions as one NAND string NS.

### (5: Cross-Sectional Structure of Semiconductor Device 1a)

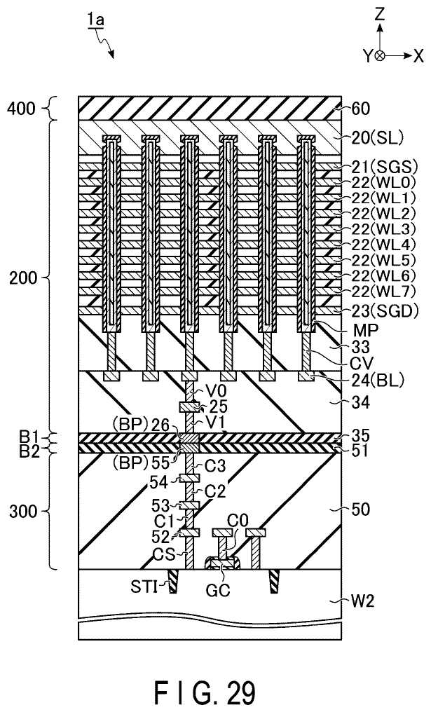

FIG. 29 is a cross-sectional view illustrating an example of a cross-sectional structure of the semiconductor device 1a according to the fourth embodiment. FIG. 29 illustrates a cross section including the memory region MR and displays coordinate axes based on the second wafer W2. As illustrated in FIG. 29, the semiconductor device 1a has a structure in which the structures of the circuit layer 200 and the bonding layer B1 illustrated in FIG. 27 are inverted up and down. In addition, the second wafer W2 includes a plurality of well regions (not illustrated). For example, a transistor is formed in each of the plurality of well regions. The plurality of well regions is separated, for example, by shallow trench isolation (ST1). The circuit layer 300 includes, for example, an insulating layer 50, conductive layers GC and 52 to 54, and contacts CS and C0 to C3. A bonding layer B2 includes, for example, an insulating layer 51 and a conductive layer 55. An interconnect layer 400 includes, for example, an insulating layer 60.

The insulating layer 50 is provided on the second wafer W2. The insulating layer 50 covers a second semiconductor circuit provided on the second wafer W2. The insulating layer 50 can include a plurality of insulating layers. The insulating layer 51 is provided on the insulating layer 50. The insulating layer 51 is in contact with the insulating layer 35. A boundary portion between the insulating layers 51 and 35 corresponds to a bonding surface between the first wafer W1 and the second wafer W2. The insulating layer 51 is, for example, a silicon oxide film.

The conductive layer GC is provided on a gate insulating film on the first wafer W1. The conductive layer GC is used as a gate electrode of the transistor. The contact C0 is provided on the conductive layer GC. Two contacts CS are connected to two impurity diffusion regions (not illustrated) corresponding to a source end and a drain end of the transistor. The conductive layers 52 are individually provided on the contacts CS and C0. The conductive layer 53 is provided on the conductive layer 52 via the contact C1. The conductive layer 54 is provided on the conductive layer 53 via the contact C2. The conductive layer 55 is provided on the conductive layer 54 via the contact C3. The conductive layer 55 corresponds to the bonding pad BP. The conductive layer 55 includes, for example, copper. The conductive layer 26 disposed so as to face the conductive layer 55 is in contact on the conductive layer 55. As a result, the conductive layer 24 (bit line BL) is electrically connected to the transistor provided on the first wafer W1.

The insulating layer 60 is provided on the conductive layer 20 (source line SL). Although not illustrated, the interconnect layer 400 includes a conductive layer connected to a semiconductor circuit included in either of the circuit layers 200 and 300. The conductive layer is connected to, for example, a pad PD provided while penetrating the insulating layer 60 (not illustrated). An interconnect connected via the bonding pad BP may be an interconnect other than the bit line BL.

### <4-2> Effects of Fourth Embodiment

The methods for manufacturing the semiconductor device 1 described in the first to third embodiments can also be used for the semiconductor device 1a as described in the fourth embodiment. Furthermore, in the fourth embodiment, a fluctuation range of a light absorption rate is suppressed by an antireflection layer 110 or 110a, whereby it is possible to suppress application of excessive heat to the circuit layer 200 at the time of laser peeling. As a result, a method of manufacturing the semiconductor device 1a according to the fourth embodiment can achieve effects similar to the effects of the first embodiment and can suppress property degradation of the memory cell transistor MT and the like due to the memory cell array 10 being heated.

### <5> Fifth Embodiment

A fifth embodiment relates to a method of manufacturing a semiconductor device 1 that suppresses fluctuations in a light absorption rate by irradiating a back surface of a first wafer W1 with laser beams having a plurality of wavelengths simultaneously. The following describes the details of the fifth embodiment, while referring mainly to differences from the first to fourth embodiments.

### <5-1> Method of Manufacturing

The following describes the method of manufacturing the semiconductor device 1 according to the fifth embodiment.

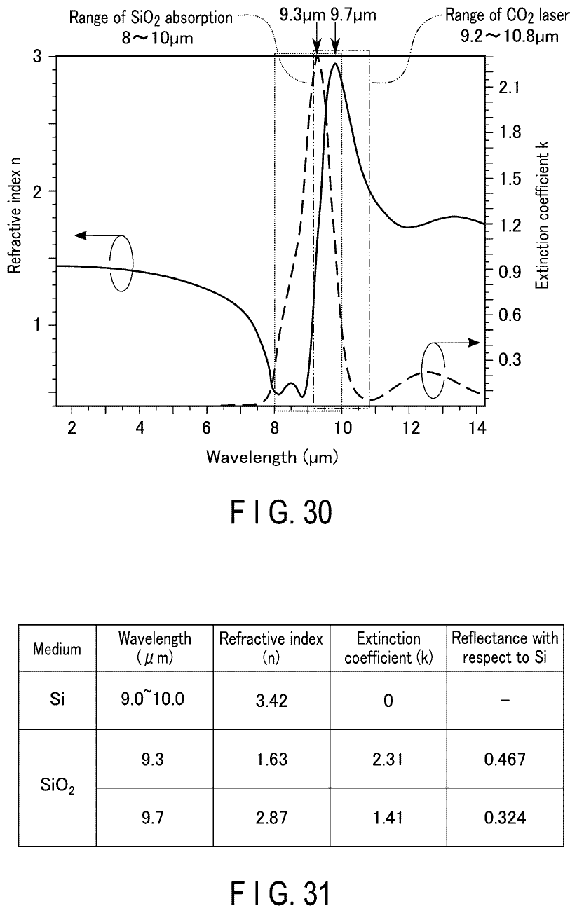

FIG. 30 is a graph illustrating a relationship between a refractive index and an extinction coefficient of a silicon oxide film (SiO₂) with respect to a wavelength of a laser beam. A horizontal axis illustrates the wavelength (μm) of the laser beam. A vertical axis on the left side illustrates a refractive index n of SiO₂ with respect to the wavelength of the laser beam. A vertical axis on the right side illustrates an extinction coefficient k of SiO₂ with respect to the wavelength of the laser beam. As illustrated in FIG. 30, an oscillation wavelength range of a CO₂ laser is 9.2 to 10.8 μm. An absorption range of SiO₂ determined based on the refractive index n and the extinction coefficient k of SiO₂ is 8 to 10 μm. Therefore, a combination of a plurality of wavelengths in the method of manufacturing the semiconductor device 1 according to the fifth embodiment is selected from 9.2 to 10 μm that is a range of wavelengths absorbed by the SiO₂ film in a case where the CO₂ laser is used. In addition, a wavelength corresponding to a peak of the refractive index n of SiO₂ is approximately 9.7 μm. A wavelength corresponding to a peak of the extinction coefficient k of SiO₂ is approximately 9.3 μm. The following describes a case where 9.3 μm and 9.7 μm are selected as a combination of two kinds of wavelengths.

FIG. 31 is a graph illustrating a relationship between a wavelength of a laser beam and reflectance with respect to Si in the method of manufacturing the semiconductor device 1 according to the fifth embodiment. As illustrated in FIG. 31, in a case where a medium is Si, a refractive index n is 3.42 and an extinction coefficient k is 0 with respect to a wavelength of 9.0 to 10.0 μm. In a case where the medium is SiO₂, the refractive index n is 1.63, the extinction coefficient k is 2.31, and reflectance of an interface with respect to Si is 0.467 with respect to a wavelength of 9.3 μm. In a case where the medium is SiO₂, the refractive index n is 2.87, the extinction coefficient k is 1.41, and the reflectance of the interface with respect to Si is 0.324 with respect to a wavelength of 9.7 μm. In other words, in the case of the wavelength of 9.7 μm, the reflectance of the interface with respect to Si is lower than the reflectance in the case of the wavelength of 9.3 μm, and this is advantageous for light absorption in a peeling layer 100.

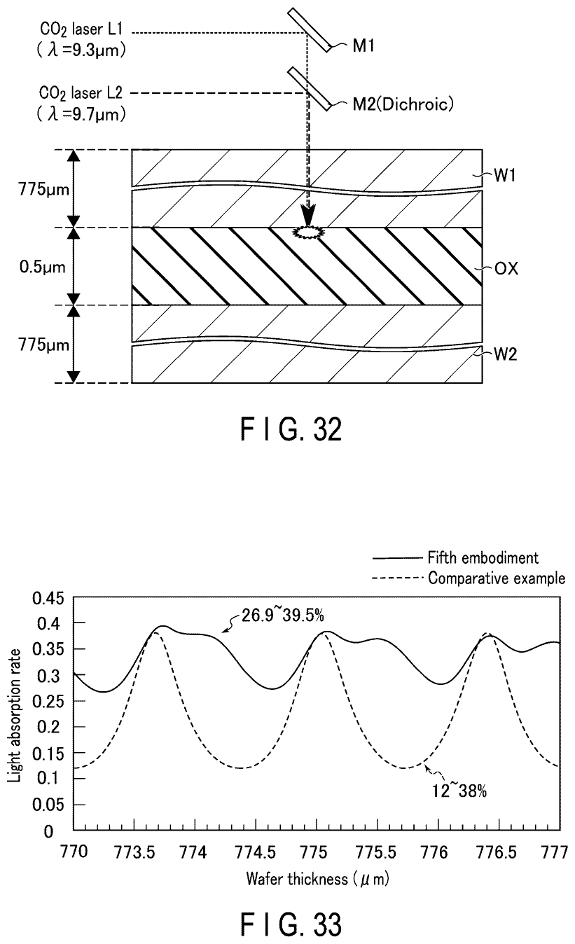

FIG. 32 is a schematic diagram illustrating an example of a structure of an object to be irradiated with the laser beam in the semiconductor device 1 according to the fifth embodiment and an example of a combination of laser beams used. As illustrated in FIG. 32, the structure used as the object to be irradiated with the laser beam in the present example is similar to a structure of the semiconductor device according to the comparative example illustrated in FIG. 9. In other words, the peeling layer 100 includes a silicon oxide film OX. Then, in the method of manufacturing the semiconductor device 1 according to the fifth embodiment, CO₂ lasers L1 and L2 are emitted on the back surface of the first wafer W1 along the same axis simultaneously. A wavelength λ=9.3 μm of the CO₂ laser L1 corresponds to the peak of the extinction coefficient k of SiO₂. A wavelength λ=9.7 μm of the CO₂ laser L2 corresponds to the peak of the refractive index n of SiO₂. A laser beam having a desired wavelength is generated, for example, by a variable wavelength CO₂ laser using grating. Such a variable wavelength CO₂ laser is configured so that a wavelength is selectable, for example, in a range of 9.2 to 10.8 μm.

For example, a structure in which laser beams having two wavelengths are emitted along the same axis simultaneously includes a mirror M1 and a dichroic mirror M2. The mirror M1 reflects a laser beam. The dichroic mirror M2 reflects a light beam emitted on a front surface and transmits a light beam emitted on a back surface. In addition, the CO₂ laser L1 is reflected by the mirror M1, passes through the dichroic mirror M2 and is emitted on the back surface of the first wafer W1. The CO₂ laser L2 is reflected by the dichroic mirror M2 and emitted on the back surface of the first wafer W1. As a result, the CO₂ lasers L1 and L2 are emitted on the back surface of the first wafer W1 along the same axis simultaneously. Then, the silicon oxide film OX generates heat by absorbing laser beams L1 and L2, and a vicinity of a portion in contact with a peeling surface of the first wafer W1 is plastically deformed based on the heat generated in the silicon oxide film OX. After that, the first wafer W1 is peeled with the silicon oxide film OX as a starting point, as in the first embodiment.

FIG. 33 is a graph illustrating a result of an optical simulation regarding fluctuations in a light absorption rate of a peeling layer with respect to a laser beam wavelength in each of the fifth embodiment and the comparative example. A horizontal axis illustrates wafer thickness (μm). A vertical axis illustrates the light absorption rate. A broken line corresponds to the light absorption rate in a case where a CO₂ laser having a single wavelength (9.3 μm) is used in the configuration of the comparative example illustrated in FIG. 9. A solid line illustrates the light absorption rate in the method of manufacturing the semiconductor device 1 according to the fifth embodiment illustrated in FIG. 32. As illustrated in FIG. 33, the light absorption rate periodically changes according to the wafer thickness. In addition, in the present example, the light absorption rate in the comparative example fluctuates in a range of 12% to 38%. In other words, a fluctuation range of the light absorption rate in the comparative example is about 26%. Meanwhile, the light absorption rate in the fifth embodiment fluctuates in a range of 26.9% to 39.5%. In other words, a fluctuation range of the light absorption rate in the fifth embodiment is about 12.6%.

### <5-2> Effects of Fifth Embodiment

As described above, in a case where the peeling layer 100 (for example, silicon oxide film OX) is caused to absorb a CO₂ laser having a wavelength of 9.3 μm in a process of peeling the first wafer W1, an interference effect of a light beam changes according to the thickness of a silicon substrate through which the laser beam passes. Specifically, a light absorption rate of the silicon oxide film OX may fluctuate by about 26%.

In contrast to this, the method of manufacturing the semiconductor device 1 according to the fifth embodiment uses the fact that a period of fluctuations in reflectance due to thin-film interference differs according to a wavelength, and a period of fluctuations in the light absorption rate, which is caused as a result of the difference of the period of fluctuations in the reflectance according to a wavelength, also differs according to a wavelength. Specifically, in the method of manufacturing the semiconductor device 1 according to the fifth embodiment, laser beams having a plurality of wavelengths such that influence caused by a change in the thickness of the silicon substrate is canceled are emitted along the same axis simultaneously, and effects of fluctuations are averaged. For example, in the case of a combination of wavelengths of 9.3 μm and 9.7 μm, periods of change are out of synchronization such that a crest and a trough cancel each other out. Therefore, it is possible to cancel the respective fluctuations in reflectance. As a result, with the combination of wavelengths of 9.3 μm and 9.7 μm, it is possible to reduce the final fluctuation ratio of light absorption to about 13%.

As described above, the method of manufacturing the semiconductor device 1 according to the fifth embodiment can more suppress fluctuations in the light absorption rate based on fluctuations in the wafer thickness by using laser beams having a plurality of wavelength in a peeling process of the first wafer W1 using laser peeling as compared with a case where a laser beam having a single wavelength is used. In other words, the method of manufacturing the semiconductor device 1 according to the fifth embodiment can suppress fluctuations in energy absorbed by the peeling layer 100 in the laser peeling and achieve a stable peeling process. As a result, the method of manufacturing the semiconductor device 1 according to the fifth embodiment can improve a yield of a manufacturing process of a semiconductor device that reuses the first wafer W1, and the method can suppress a manufacturing cost of the semiconductor device.

### (Other Combinations of Plurality of Wavelengths)

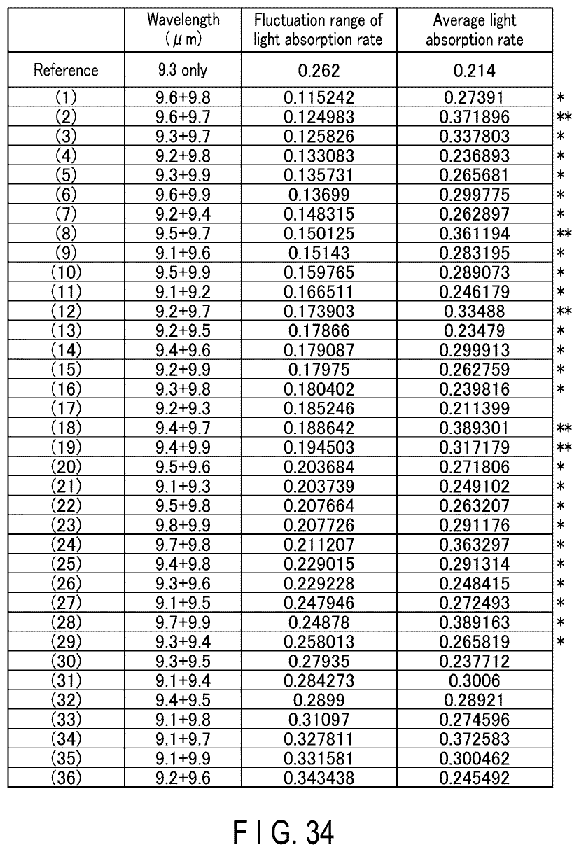

FIG. 34 is a table illustrating a result of an optical simulation regarding a fluctuation range of a light absorption rate and an average light absorption rate for each combination of laser beams in the method of manufacturing the semiconductor device 1 according to the fifth embodiment. FIG. 34 is a table illustrating 36 kinds ((1) to (36)) of relationships among a combination of wavelengths (μm) of laser beams used, a fluctuation range of a light absorption rate, and an average light absorption rate. Each of two numbers illustrated in a column of wavelength corresponds to wavelengths to be combined. As a reference, a case where only a laser beam having a single wavelength (9.3 μm) is used is illustrated. The fluctuation range of the light absorption rate in the reference is 0.262, and the average light absorption rate in the reference is 0.214. The fluctuation range of the light absorption rate is preferably smaller than the reference and more preferably 0.2 or less. The average light absorption rate is preferably larger than the reference and more preferably 0.3 or more. The following lists simulation results of the 36 kinds of relationships. (Number) wavelengths, the fluctuation range of the light absorption rate, the average light absorption rate
(1) 9.6+9.8, 0.115242, 0.27391
(2) 9.6+9.7, 0.124983, 0.371896
(3) 9.3+9.7, 0.125826, 0.337803
(4) 9.2+9.8, 0.133083, 0.236893
(5) 9.3+9.9, 0.135731, 0.265681
(6) 9.6+9.9, 0.13699, 0.299775
(7) 9.2+9.4, 0.148315, 0.262897
(11) 9.1+9.2, 0.166511, 0.246179
(12) 9.2+9.7, 0.173903, 0.33488
(13) 9.2+9.5, 0.17866, 0.23479
(8) 9.5+9.7, 0.150125, 0.361194
(9) 9.1+9.6, 0.15143, 0.283195
(10) 9.5+9.9, 0.159765, 0.289073
(11) 9.1+9.2, 0.166511, 0.246179
(12) 9.2+9.7, 0.173903, 0.33488
(13) 9.2+9.5, 0.17866, 0.23479

(14) 9.4+9.6, 0.179087, 0.299913

(15) 9.2+9.9, 0.17975, 0.262759

(16) 9.3+9.8, 0.180402, 0.239816

(17) 9.2+9.3, 0.185246, 0.211399

(18) 9.4+9.7, 0.188642, 0.389301

(19) 9.4+9.9, 0.194503, 0.317179

(20) 9.5+9.6, 0.203684, 0.271806

(21) 9.1+9.3, 0.203739, 0.249102

(22) 9.5+9.8, 0.207664, 0.263207

(25) 9.4+9.8, 0.229015, 0.291314

(26) 9.3+9.6, 0.229228, 0.248415

(27) 9.1+9.5, 0.247946, 0.272493

(23) 9.8+9.9, 0.207726, 0.291176

(24) 9.7+9.8, 0.211207, 0.363297

(28) 9.7+9.9, 0.24878, 0.389163

(29) 9.3+9.4, 0.258013, 0.265819

(30) 9.3+9.5, 0.27935, 0.237712

(31) 9.1+9.4, 0.284273, 0.3006

(32) 9.4+9.5, 0.2899, 0.28921

(33) 9.1+9.8, 0.31097, 0.274596

(34) 9.1+9.7, 0.327811, 0.372583

(35) 9.1+9.9, 0.331581, 0.300462

(36) 9.2+9.6, 0.343438, 0.245492

As described above, in a case where laser beams having a plurality of wavelengths are selected from the oscillation wavelength range of the CO₂ laser, a combination in a wide range of 9.2 to 10 μm is effective. For example, in (1) to (29) in FIG. 34, the fluctuation range of the light absorption rate is smaller than the reference. In (1) to (19) in FIG. 34, the fluctuation range of the light absorption rate is 0.2 or less. In (1) to (16) and (18) to (36) in FIG. 34, the average light absorption rate is larger than the reference. In (2), (3), (8), (12), (18), (19), (24), (28), (31), (34), and (35) in FIG. 34, the average light absorption rate is 0.3 or more. In (1) to (16) and (18) to (29) in FIG. 34, the fluctuation range of the light absorption rate is smaller than the reference and the average light absorption rate is larger than the reference (items added with “*” in FIG. 34). In (2), (3), (8), (12), (18), and (19) in FIG. 34, the fluctuation range of the light absorption rate is 0.2 or less and the average light absorption rate is 0.3 or more (items added with “**” in FIG. 34).

A combination of laser beams having a plurality of wavelengths, which is good in terms of both the fluctuation range of the light absorption rate and the average light absorption rate, preferably includes laser beams having any wavelengths in a range of 9.7 to 9.9 μm and more preferably includes a laser beam having a wavelength of 9.7 μm. Specifically, as laser beams having a plurality of wavelengths, a first laser beam having any wavelength in a range of 9.7 to 9.9 μm is combined with a second laser beam having a wavelength that is a wavelength in a range of 9.2 to 9.9 μm and that is different from the wavelength of the first laser beam. In addition, in a case where a laser beam having a wavelength of 9.6 μm is selected, the laser beam is preferably combined with a laser beam having a wavelength that is any wavelength in a range of 9.3 to 9.9 μm and that is different from the wavelength of 9.6 μm. The method of manufacturing the semiconductor device 1 according to the fifth embodiment can suppress fluctuations in the light absorption rate and increase the average light absorption rate by using a combination of appropriate wavelengths as illustrated in FIG. 34.

Note that the numerical values for the wavelengths exemplified in the present specification are not limited to numerical values that completely match the numerical values exemplified in the present specification. For example, in a case where there is a numerical value at the second decimal place in a numerical value of a wavelength, it suffices that a numerical value obtained by rounding off the numerical value at the second decimal place to the first decimal place corresponds to the value illustrated above.

### <5-3> Modifications of Fifth Embodiment

The following describes modifications of the fifth embodiment.

The method of manufacturing the semiconductor device 1 according to the fifth embodiment may be combined with any of the first to third embodiments. In other words, in any of the first to third embodiments, laser beams having a plurality of wavelength may be emitted to a back surface of a first wafer W1 along the same axis simultaneously. Even in such as case, fluctuations in a light absorption rate can be suppressed as in the fifth embodiment.

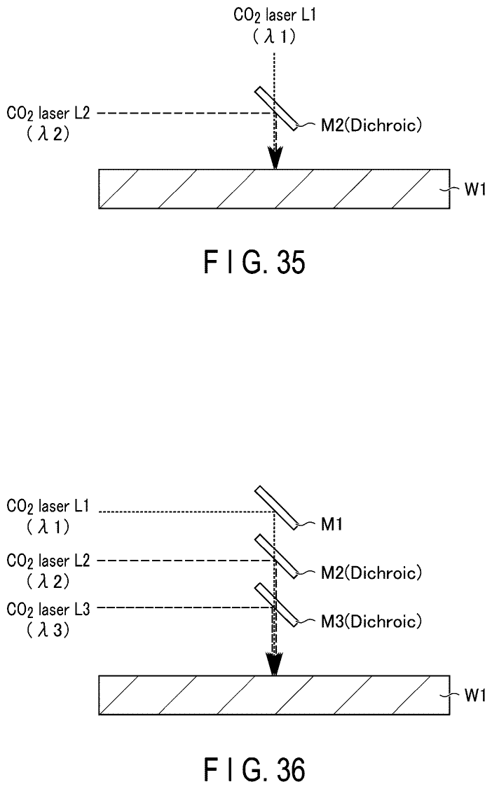

FIG. 35 is a schematic diagram illustrating a method for emitting a laser beam in a first modification of the fifth embodiment. FIG. 35 exemplifies a semiconductor substrate W1 that is an object to be irradiated with a laser beam in a set of the semiconductor substrate W1, a silicon oxide film OX, and a semiconductor substrate W2. FIG. 35 also exemplifies a case where the semiconductor substrate W1 is irradiated with laser beams having two wavelengths, which are a CO₂ laser L1 (wavelength λ1) and a CO₂ laser L2 (wavelength λ2), along the same axis simultaneously. As illustrated in FIG. 35, in a case where the method of manufacturing the semiconductor device 1 according to the fifth embodiment uses laser beams having two wavelengths, a mirror M1 may be omitted. In other words, a configuration of a mirror used in a case where laser beams having two wavelengths are emitted along the same axis simultaneously can be achieved even with one dichroic mirror M2.

FIG. 36 is a schematic diagram illustrating a method for emitting a laser beam in a second modification of the fifth embodiment. FIG. 36 exemplifies a semiconductor substrate W1 that is an object to be irradiated with a laser beam in a set of the semiconductor substrate W1, a silicon oxide film OX, and a semiconductor substrate W2. FIG. 36 also exemplifies a case where the semiconductor substrate W1 is irradiated with laser beams having three wavelengths, which are a CO₂ laser L1 (wavelength λ1), a CO₂ laser L2 (wavelength λ2), and a CO₂ laser L3 (wavelength λ3), along the same axis simultaneously. As described above, the method of manufacturing the semiconductor device 1 according to the fifth embodiment may use a combination of laser beams having three or more wavelengths. In a case where laser beams having three wavelengths are emitted along the same axis simultaneously, for example, a mirror M1 and dichroic mirrors M2 and M3 are used. Specifically, the CO₂ laser L1 is reflected by the mirror M1, passes through the dichroic mirrors M2 and M3, and is emitted on the semiconductor substrate W1. The CO₂ laser L2 is reflected by the dichroic mirror M2, passes through the dichroic mirror M3, and is emitted on the semiconductor substrate W1. The CO₂ laser L3 is reflected by the dichroic mirror M3 and is emitted on the semiconductor substrate W1. As a result, the CO₂ lasers L1, L2, and L3 can be emitted on the semiconductor substrate W1 along the same axis simultaneously. As described above, in the method of manufacturing the semiconductor device 1 according to the fifth embodiment, laser beams having three or more wavelengths may be emitted along the same axis simultaneously through a plurality of dichroic mirrors.

### <6> Modifications and Like

Each embodiment described above can be variously modified.

In the above embodiments, each of the circuit configurations, the planar layouts, and the cross-sectional structures of the semiconductor devices 1 and 1a can be appropriately changed. For example, a semiconductor layer 41 of a memory pillar MP and a source line SL may be connected via a bottom of a memory pillar MP. The memory pillar MP may have a structure in which two or more pillars are connected in a Z direction. The memory pillar MP may have a structure in which a pillar corresponding to a select gate line SGD and a pillar corresponding to a word line WL are connected. Each contact may be connected by a plurality of contacts connected in the Z direction. A conductive layer may be inserted into a connecting portion of the plurality of contacts. The number of interconnect layers and the number of contacts included in the semiconductor device 1a can be appropriately changed.

In the present specification, “connection” means being electrically connected and does not exclude, for example, being electrically connected via another element in the middle. “Being electrically connected” may be done via an insulator as long as things electrically connected via the insulator can operate in a manner similar to things electrically connected. “Columnar” means being a structure provided in a hole formed in a manufacturing process of the semiconductor device 1. A “width” means, for example, a width of a constituent element in an X direction or a Y direction. A “wafer” or “semiconductor substrate” may be referred to as a “substrate”. A “semiconductor layer” may be referred to as a “conductive layer”. A “region” may be regarded as being in a configuration in which the region is included by a substrate used as a reference. A “planar position” means a position of the constituent element in a planar layout. A “top (plan) view” corresponds to, for example, viewing an object from a front side of the wafer. In the present specification, as a reference for measuring a pitch, an end of a pattern in the X direction or the Y direction may be used, or a central portion of a pattern may be used. Materials used for antireflection layers 110 and 110a, a light absorption layer 120, and the like can include impurities. It suffices that these layers use the silicon oxide film, the polysilicon, and the like described in the above embodiments as main materials.

While certain embodiments of the present invention have been described, these embodiments have been presented by way of example only, and are not intended to limit the scope of the invention. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device in which a first substrate and a second substrate on which a first circuit layer and a second circuit layer different from each other are formed, respectively are bonded, the method comprising:
forming, on the first substrate, a first layer having a refractive index lower than a refractive index of the first substrate;
forming, on the first layer, a second layer having a refractive index lower than a refractive index of the first layer;
forming the first circuit layer on the second layer;
bonding a front surface of the first substrate and a front surface of the second substrate after forming the first circuit layer;
irradiating a back surface of the first substrate with a laser beam after bonding the first substrate and the second substrate; and
peeling the first substrate so that the first circuit layer remains on a side of the second substrate after irradiating the back surface of the first substrate with the laser beam.

2. The method of manufacturing the semiconductor device according to claim 1, wherein
the first substrate is a silicon substrate,
the second layer is a silicon oxide film, and
the laser beam is a CO₂ laser.

3. The method of manufacturing the semiconductor device according to claim 1, wherein
the second layer includes a first material, and
the first layer includes a portion formed of the first material and a portion formed of a second material having a refractive index higher than a refractive index of the first material.

4. The method of manufacturing the semiconductor device according to claim 3, wherein
the first material is a silicon oxide film, and
the second material is polysilicon.

5. The method of manufacturing the semiconductor device according to claim 3, wherein
the second material is formed in a shape of a line-and-space pattern in the first layer.

6. The method of manufacturing the semiconductor device according to claim 5, wherein
a pitch of the line-and-space pattern of the second material is less than a wavelength of the laser beam.

7. The method of manufacturing the semiconductor device according to claim 6, wherein
the pitch of the line-and-space pattern of the second material is one fifth or less of the wavelength of the laser beam.

8. The method of manufacturing the semiconductor device according to claim 7, wherein
a line pattern included in the line-and-space pattern of the second material is divided into a plurality of sub-patterns, and a pitch of the sub-patterns is smaller than the pitch of the line-and-space pattern of the second material.

9. The method of manufacturing the semiconductor device according to claim 5, the method further comprising:
controlling polarization of the laser beam so that the polarization of the laser beam is polarization parallel to the line-and-space pattern of the second material or polarization orthogonal to the line-and-space pattern of the second material in case of irradiating the back surface of the first substrate with the laser beam.

10. The method of manufacturing the semiconductor device according to claim 1, wherein
the first circuit layer includes a memory cell, and
the second circuit layer includes a CMOS circuit.

11. The method of manufacturing the semiconductor device according to claim 1, wherein
the irradiating the back surface of the first substrate with the laser beam after bonding the first substrate and the second substrate includes irradiating the back surface of the first substrate with laser beams having a plurality of wavelengths along the same axis simultaneously.

12. The method of manufacturing the semiconductor device according to claim 11, wherein
the wavelengths include a first wavelength included in a range of 9.2 to 10 micrometers and a second wavelength included in the range of 9.2 to 10 micrometers, the second wavelength being different from the first wavelength.

13. The method of manufacturing the semiconductor device according to claim 12, wherein
the first wavelength is included in a range of 9.7 to 9.9 micrometers and the second wavelength is included in a range of 9.2 to 9.9 micrometers.

14. The method of manufacturing the semiconductor device according to claim 12, wherein
the wavelengths include 9.3 micrometers or 9.6 micrometers and 9.7 micrometers.

15. The method of manufacturing the semiconductor device according to claim 12, wherein
the first wavelength is 9.6 micrometers and the second wavelength is included in a range of 9.3 to 9.9 micrometers.

16. The method of manufacturing the semiconductor device according to claim 12, wherein
the first wavelength is 9.2 micrometers and the second wavelength is included in a range of 9.4 to 9.5 micrometers.
